(19) United States
(12) Patent Application Publication
(10) Pub. No.: US 2025/0164871 A1
(43) Pub. Date: May 22, 2025

(54) METHODS AND APPARATUS TO IMPROVE DETECTION OF DEFECTS IN PHOTOMASK BLANKS

(71) Applicant: Intel Corporation, Santa Clara, CA (US)

(72) Inventors: Yoshihiro Tezuka, Tsukuba (JP); Annelise Rachel Beck, Sunnyvale, CA (US); Chang Ju Choi, Fremont, CA (US); Eric Alan Frendberg, Dublin, CA (US); Richard Seiji Oka, San Jose, CA (US)

(21) Appl. No.: 18/512,842

(22) Filed: Nov. 17, 2023

(51) Int. Cl. G03F 1/84; G01N 21/88; G01N 21/956

(52) U.S. Cl. CPC G03F 1/84; G01N 21/8851; G01N 21/95692; G01N 2021/8861

(57) ABSTRACT

Systems, apparatus, articles of manufacture, and methods to improve detection of defects in photomask blanks are disclosed. An example apparatus includes: interface circuitry; machine readable instructions; and programmable circuitry to at least one of instantiate or execute the machine readable instructions to: identify a first potential defect in a photomask blank based on an intensity value not satisfying a first threshold but satisfying a second threshold, the intensity value based on pixel data associated with a first type of inspection of the photomask blank; and designate the first potential defect as a detected defect based on first coordinates for the first potential defect being within a threshold distance of second coordinates for a second potential defect, the second potential defect identified based on a second type of inspection of the photomask blank.

### FIELD OF THE DISCLOSURE

This disclosure relates generally to semiconductor device fabrication and, more particularly, to methods and apparatus to improve detection of defects in photomask blanks.

### BACKGROUND

Semiconductor device fabrication includes various processes to manufacture integrated circuits or chips. Many processes involved in semiconductor device fabrication involve the use of photolithography. Photolithography involves the application of light onto a layer of light-sensitive material (e.g., a photoresist, also sometimes referred to simply as a resist) in a controlled manner to produce a pattern in the layer of material in which portions of the layer of material are retained while other portions are removed. Often, the exposure of light onto a photoresist is controlled through the use of a photolithography mask (e.g., a photomask or simply mask) between the light source and the photoresist.

### BRIEF DESCRIPTION OF THE DRAWINGS

FIG. 1 illustrates an example system that includes an example photomask to photolithographically pattern materials in an integrated circuit (IC) package.

FIG. 2 illustrates an example support substrate inspection system that may be implemented to detect defects in the support substrate of an example photomask blank.

FIG. 3 illustrates an example optical multilayer inspection system that may be implemented to detect defects in the multilayer of an example photomask blank.

FIG. 4 illustrates an example actinic multilayer inspection system that may be implemented to detect defects in the multilayer of an example photomask blank.

FIG. 5 illustrates a completed photomask blank fabricated following implementation of the inspection systems of FIGS. 2-4.

FIG. 6 is a block diagram of an example implementation of the photomask inspection circuitry of FIGS. 2-4 to identify defects (and determine their precise coordinates) in a photomask blank (e.g., the mask blank).

FIGS. 7 and 8 are flowcharts representative of example machine readable instructions and/or example operations that may be executed, instantiated, and/or performed by example programmable circuitry to implement the photomask inspection circuitry 214 of FIG. 6.

FIG. 9 is a block diagram of an example processing platform including programmable circuitry structured to execute, instantiate, and/or perform the example machine readable instructions and/or perform the example operations of FIGS. 7 and 8 to implement the photomask inspection circuitry 214 of FIG. 6.

FIG. 10 is a block diagram of an example implementation of the programmable circuitry of FIG. 9.

FIG. 11 is a block diagram of another example implementation of the programmable circuitry of FIG. 9.

FIG. 12 is a block diagram of an example software/firmware/instructions distribution platform (e.g., one or more servers) to distribute software, instructions, and/or firmware (e.g., corresponding to the example machine readable instructions of FIGS. 7 and 8) to client devices associated with end users and/or consumers (e.g., for license, sale, and/or use), retailers (e.g., for sale, re-sale, license, and/or sub-license), and/or original equipment manufacturers (OEMs) (e.g., for inclusion in products to be distributed to, for example, retailers and/or to other end users such as direct buy customers).

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

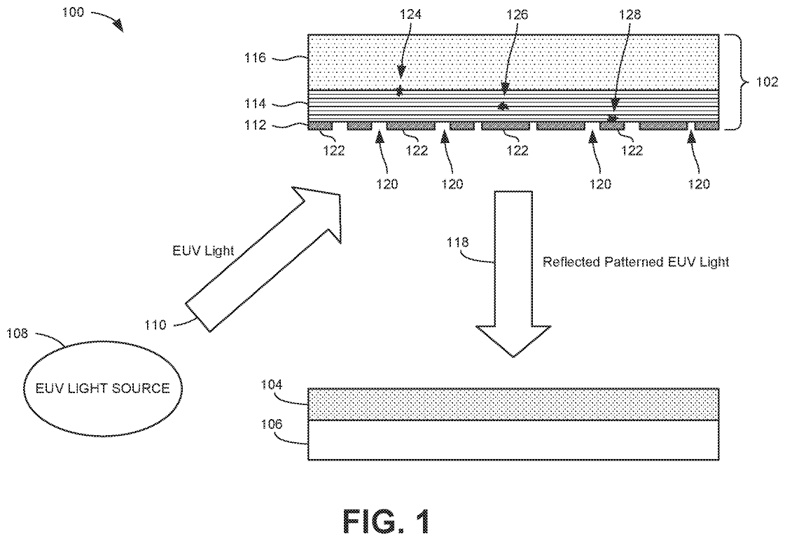

FIG. 1 illustrates an example system 100 that includes an example photomask 102 (or simply mask), constructed in accordance with teachings disclosed herein, to photolithographically pattern a layer of light-sensitive material (e.g., a photoresist) 104 on some underlying layer or substrate 106. In some instances, the underlying substrate 106 corresponds to a portion of an IC package. More particularly, in some instances, the underlying substrate 106 corresponds to a particular layer within a semiconductor die (e.g., an IC chip) within the IC package, a particular layer within a package substrate for the IC package, and/or any other suitable substrate. In some instances, the photoresist 104 is patterned to define openings in the photoresist 104 that can then be used as a mask to create corresponding openings in the underlying substrate 106 (e.g., through an etching process that removes portions of the underlying substrate exposed through the openings in the photoresist 104). In some instances, instead of removing portions of the underlying substrate 106 exposed through the openings in the photoresist 104, the openings in the photoresist 104 can be filled with a material to be added onto the underlying substrate 106 at the locations defined by the openings. In some instances, the photoresist 104 is removed after subsequent processing associated with the use of the patterned openings have been completed. In other instances, the photoresist 104 is retained on the underlying substrate 106 and remains as part of the final product (e.g., some portion of an IC package).

The system 100 of FIG. 1 is an extreme ultraviolet (EUV) lithography system. Accordingly, as shown in FIG. 1, the system 100 includes an EUV light source 108 that produces EUV light 110. More particularly, the EUV light source 108 can be a laser driven light source (e.g., based on tin plasma) that produces extreme ultraviolet (EUV) light (e.g., ultraviolet light at a wavelength of approximately 13.5 nanometers (nm)). As shown in FIG. 1, the EUV light 110 is directed towards the photomask 102. The photomask 102 includes an absorber layer 112 (also referred to herein simply as an absorber) having a defined pattern on an outer surface of a multilayer region 114 (also referred to herein simply as a multilayer). The absorber 112 is an opaque material capable of absorbing the EUV light 110. In some examples, the absorber 112 is implemented with chromium. However, the absorber 112 can be implemented using any other suitable opaque material. The multilayer 114 is defined by a stack of thin films or layers of materials capable of reflecting the EUV light 110. More particularly, in some examples, the multilayer 114 includes alternating layers of molybdenum and silicon.

As shown in FIG. 1, both the patterned absorber 112 and the multilayer 114 are carried by a supporting substrate 116. In some examples, the support substrate 116 is a solid piece of glass (e.g., a glass pane, panel, or sheet). In some examples, the glass substrate includes at least one of: aluminosilicate, borosilicate, alumino-borosilicate, silica, and/or fused silica. In some examples, the glass substrate includes one or more additives including: aluminum oxide (Al2O3), boron trioxide (B2O3), magnesia oxide (MgO), calcium oxide (CaO), stoichiometric silicon oxide (SrO), barium oxide (BaO), stannic oxide (SnO2), nickel alloy (Na2O), potassium oxide (K2O), phosphorus trioxide (P2O3), zirconium dioxide (ZrO2), lithium oxide (Li2O), titanium (Ti), and/or zinc (Zn). In some examples, the glass substrate includes silicon and oxygen. In some examples, the glass substrate includes silicon, oxygen and/or one or more of aluminum, boron, magnesium, calcium, barium, tin, sodium, potassium, strontium, phosphorus, zirconium, lithium, titanium, and/or zinc. In some examples, the glass substrate includes at least 13 percent silicon by weight and at least 16 percent oxygen by weight. In some examples, the glass substrate is a layer of glass including silicon, oxygen and aluminum. In some examples, the glass substrate includes at least 13 percent silicon by weight, at least 16 percent oxygen by weight, and at least 5 percent aluminum by weight. In some examples, the glass substrate is an amorphous solid glass layer. In some examples, the support substrate 116 is composed of a material other than glass.

As the EUV light 110 reaches the photomask 102, the absorber 112 absorbs the EUV light 110. The reflective films within the multilayer 114 reflect at least a portion of the EUV light (referred to herein as reflected patterned EUV light 118) that is directed toward the photoresist 104. The reflected patterned EUV light 118 is defined by the pattern of the absorber 112. That is, as shown in FIG. 1, the pattern of the absorber 112 is defined by openings 120 between opaque regions 122 of the absorber 112. The opaque regions 122 absorb at least a portion of the EUV light 110 so that the absorbed portion of the EUV light 110 is not reflected towards the photoresist 104. the openings 120 expose portions of the underlying multilayer 114 and the exposed portions of the multilayer 114 will reflect at least a portion of the EUV light 110 (e.g., the reflected patterned EUV light 118) towards the photoresist 104.

In the illustrated example, the photoresist 104 is a photo-sensitive material such that the portions of the photoresist 104 exposed to the reflected patterned EUV light 118 will react to the light and change characteristics. Specifically, in some instances, the photoresist 104 exposed to light will harden such that when a developer solution is applied to the photoresist 104, the portions that remain relatively soft (e.g., the portions not exposed to the light) will be removed while the hardened portions will remain. In this manner the pattern defined by the opaque regions 122 of the absorber 112 on the photomask 102 are transferred to the photoresist 104. In other instances, the portions of the photoresist 104 exposed to the light 118 change so that they remain when a developer solution is applied while the rest of the photoresist 104 is removed. In this manner the pattern defined by the openings 120 in the absorber 112 (e.g., the inverse of the pattern defined by the opaque regions 122) is transferred to the photoresist 104.

In some circumstances it is possible for reliable transfer of a pattern from the photomask 102 to the photoresist 104 to be undermined due to defects 124, 126, 128 in the photomask 102. More particularly, defects in the multilayer 114 can result in the EUV light 110 incident on the photomask 102 being scattered or reflected at an angle other than intended. Due to the scattering/unintended reflection of light, portions of the photoresist 104 that are not intended to be exposed to the resulting reflected patterned EUV light 118 may be inadvertently exposed to the EUV light. Additionally or alternatively, portions of the photoresist 104 that were intended to be exposed to the EUV light 118 may not be exposed to the EUV light 118. Either of these untended outcomes can result in errors or defects in the photoresist 104.

The above noted defects in the multilayer 114 (which can result in errors in the pattern transfer to the photoresist 104) can arise from defects in the underlying support substrate 116 that propagate into the multilayer (as represented by the first defect 124 in FIG. 1). Further, defects can occur at any of one or more layers in the middle of the multilayer 114 (as represented by the second defect 126 in FIG. 1). Further still, defects can occur at the outer surface of the multilayer 114 where the absorber 112 is located (as represented by the third defect 126 in FIG. 1).

Ideally, the photomask 102 would not have any defects. However, due to practical realities and limitations of fabrications processes, this is not always possible. Accordingly, to mitigate against the imperfections in photomask fabrication, in examples disclosed herein, the locations of the defects 124, 126, 128 within the photomask 102 are determined and the pattern formed in the absorber 112 is shifted to place the defects 124, 126, 128 in alignment with the opaque regions 122. That is, the defects 124, 126, 128 are detected and located in the photomask prior to patterning the absorber 112 (e.g., when the photomask is still a photomask blank). The precise location(s) of the detected defect(s) 124, 126, 128 in the blank are used to define where the openings 120 in the absorber 112 can be positioned to avoid the defects. While the spatial relationship of different ones of the openings 120 are fixed relative to one another, the pattern as a whole can be shifted across the plane of the absorber 112 to shift the position of the openings 120 relative to the defects 124, 126, 128. In this manner, as shown in FIG. 1, each of the three defects 124, 126, 128 are covered by (e.g., aligned with) an opaque region 122. As a result, the defects 124, 126, 128 will not affect the light reflected by the multilayer 114 at the regions corresponding to the openings 120 in the absorber 112 (which are spaced apart from the defects 124, 126, 128).

Identifying defects in a mask blank is a time consuming and, therefore, costly process. While the presence of some defects can be detected relatively quickly and easily, a significant amount of time is needed to determine the precise location(s) (e.g., acquire the precise coordinates) of the detected defect(s) in the mask blank. Specifically, determining the precise location of a defect is time consuming because it relies on magnifying optics that precisely inspect the specific area of interest rather than being based on a relatively rough (course) scan or image of the mask blank. Furthermore, this process is not only time consuming for any given defect, but the overall time to determine precise coordinates for multiple detected defects is increased when the detected defects include false positives (e.g., locations in which a defect was detected but no defect actually exists). That is, if the defects for which precise coordinates are to be determined includes many false positives, the many false positives result in a collective waste of extra time in determining precise coordinates for defect(s) that do not exist. Moreover, the detection of more than a threshold amount of false positives can result in a perceived unacceptable defect density (based on both actual defects and the false positives) such that the mask blank is discarded, even though this would not be necessary if the false positives were excluded. Accordingly, it is advantageous to reduce the number of false positives. This can be accomplished by increasing the thresholds that collected inspection data must satisfy to be designated as indicative of a defect. However, increasing the thresholds used to detect defects, so as to exclude false positives, can also increase the resulting number of false negatives (e.g., actual defects in a photomask blank that avoid detection). Thus, there is a tradeoff in setting suitable thresholds for photomask blank defect detection between identifying all real defects (e.g., avoiding false negatives) while at the same time reducing unnecessary analysis to identify the precise coordinates for defects that don't actually exist (e.g., avoiding false positives).

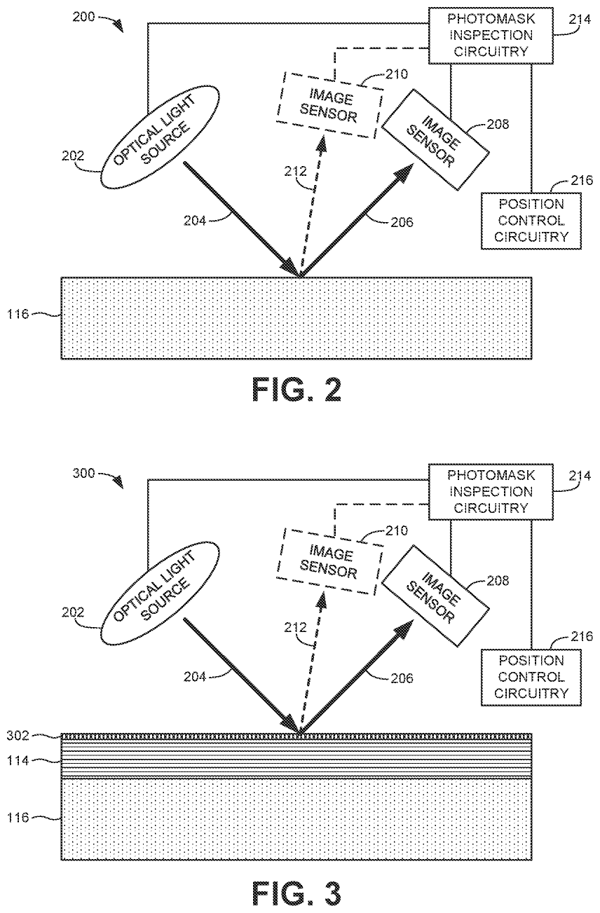

Examples disclosed herein enable a reduction in (e.g., elimination of) false positive defect detections while at the same time implementing measures to reduce (e.g., eliminate) false negatives. More particularly, in some examples, at different stages during the fabrication process of a photomask blank (also referred to herein as a mask blank or simply a blank), different types of inspection processes are implemented to identify potential defects in the components of the mask blank. An example process to manufacture and inspect a photomask blank using the different types of inspection processes is detailed further below in connection with FIGS. 2-5. In general, the different inspection processes may involve shining light onto some part of the mask blank and then using an image sensor to capture the light reflected and/or scattered off the surface of the mask blank. The Intensity of light captured off of (e.g., based on scattering or reflection from) different locations of the surface of the mask blank can indicate the presence of a defect at those locations. Specifically, in some examples, the intensity of captured light emanating from a given region (e.g., the intensity of light indicated by the intensity values associated with a small cluster or group of pixels in the image data captured by an image sensor) is compared to a first threshold. If the intensity satisfies (e.g., equals and/or exceeds) the first threshold, the location associated with that intensity is designated as the location of a detected defect.

In examples disclosed herein, the first threshold is set to reduce (e.g., eliminate, exclude) false positive detections of defects. That is, the first threshold is set such that there is a relatively high degree of confidence that intensity values satisfying the first threshold correspond to an actual defect. In other words, in some examples, the first threshold is set relatively high (assuming relatively high intensity values are indicative of defects). As noted above, setting the first threshold to reduce false positives in this manner increases the possibility of some defects being missed (e.g., false negatives). Accordingly, in some examples, if the intensity value associated with light captured in image data associated with a given location on a mask blank does not satisfy the first threshold, the intensity value is compared to a second threshold. The second threshold is set to reduce (e.g., eliminate, exclude) false negatives. That is, the second threshold is set to ensure that many (e.g., most, all) defects that were missed based on the analysis using the first threshold will be detected based on an analysis using the second threshold. In other words, the second threshold is set relatively low (assuming relatively high intensity values are indicative of defects). That is, in some examples, the second threshold is lower than the first threshold.

While the analysis based on the second threshold is expected to capture most, if not all, defects missed by the analysis based on the first threshold, the analysis based on the second threshold is likely to produce false positives (e.g., incorrectly identify locations as corresponding to defects where no defect exists). Accordingly, if the intensity value associated with light captured in image data associated with a given region satisfies (e.g., equals and/or exceeds) the second threshold (but not the first threshold), the location is designated as the location of a potential defect (also referred to herein as a defect candidate) for which additional analysis will be performed before the potential defect is confirmed with a sufficient degree of confidence to correspond to an actual defect (and not merely a false positive).

The phrase “potential defect” (or “defect candidate”) is used herein in contrast to the phrase “detected defect.” Specifically, as used herein, the phrase “detected defect” is a defect that has been identified (detected) with sufficient reliability or certainty to be designated as a defect for which the time consuming process of determining precise coordinates of the defect's location using precise magnifying optics is to be implemented. For instance, a defect identified based on an intensity value (corresponding to reflected and/or scattered light captured by an image sensor) that satisfies the first threshold constitutes a “detected defect.” By contrast, as used herein, the phrase “potential defect” (or “defect candidate”) is a possible defect that has been identified (detected), but not with sufficient reliability or certainty to proceed with the process of determining the precise coordinates of the defect. For instance, a defect identified based on an intensity value that does not satisfy the first threshold but at least satisfies the second threshold constitutes a “potential defect.” A “potential defect” defect may be elevated to or re-designated as a “detected defect” (for which precise coordinates are determined) if (e.g., only if) there is some additional confirmation that the defect is not a false positive. Identifying “potential defects” based on a comparison of intensity values to the second threshold serves to ensure that most, if not all, true defects (as opposed to false negatives) are identified. Further, elevating such “potential defects” to “detected defects” after (e.g., only after) there is some additional corroborating evidence that ensures most, if not all, false positives are avoided. The resulting detection of defects in a photomask blank is more accurate than existing approaches and the subsequent process of determining the precise coordination of the detected defects can be done more efficiently because time will not be wasted on locations that are not actually associated with a defect. Furthermore, identifying defects in mask blanks as disclosed herein, also enables the creation of finalized photomasks (e.g., after patterning of the absorber 112) to increase wafer yield of end products by reducing (e.g., eliminating) seeds of stochastic defects in wafer lithography processes.

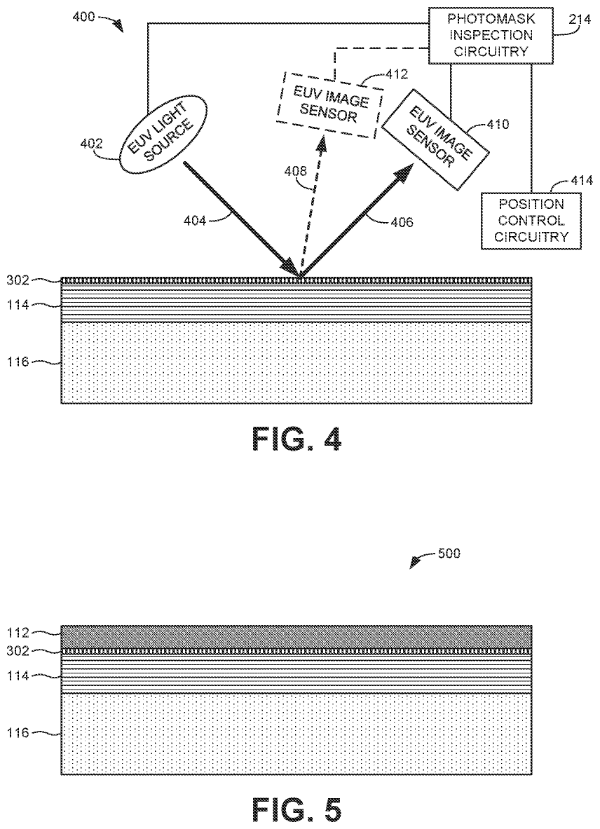

In some examples, the additional information relied on to elevate a potential defect (identified using a first inspection process) to a detected defect is based on the results of a second inspection process of a different type. Examples of such types of photomask blank inspections include (1) an initial inspection of the support substrate 116 prior to the addition of the multilayer 114 (as detailed below in connection with FIG. 2), (2) an optical inspection of the multilayer 114 prior to addition of the absorber 112 (as detailed below in connection with FIG. 3), and/or (3) an actinic inspection of the multilayer 114 prior to the addition of the absorber 112 (as detailed below in connection with FIG. 4). As used herein, the term “optical” in the context of an optical inspection means an inspection that relies on light with wavelengths in the visible spectrum and/or the ultraviolet spectrum (e.g., wavelengths between approximately 790 nm and approximately 100 nm). As used herein, the term “actinic” in the context of an actinic inspection means an inspection that relies on light used in extreme ultraviolet (EUV) lithography (e.g., light with a wavelength of approximately 13.5 nm). In some examples, a potential defect identified using a first type of inspection process is elevated to a detected defect when a second type of inspection process also identified a potential defect at the same or similar location. The locations may not be at exactly the same location because, as discussed above, such locations are based on rough coordinates for the potential defects determined prior to the determination of the precise coordinates, which is an analysis that is to occur later in the overall process after the potential defect has been elevated to a detected defect. Accordingly, in some examples, the potential defects identified using the separate processes are determined to be at the same or similar location when the rough coordinates of the potential defects (e.g., respectively determined by the different inspection processes) are within a threshold distance of one another (e.g., within approximately 100 μm).

In some examples, the additional information relied on to elevate a potential defect (identified using a first inspection process) to a detected defect is based on an analysis of the inspection data at a finer level of granularity. Whether based on visible light or ultraviolet light, inspection processes may involve an image sensor that captures image data corresponding to pixel data representative of light reflected or scattered off the surface of the photomask blank. In some examples, an initial analysis of the image data is accomplished by analyzing the intensity values of multiple pixels in a cluster or group of pixels. For example, a single group of pixels may include 4 pixels in a 2×2 array. In other examples, a different number and/or different arrangement of pixels may be associated with a single group. In some examples, the separate intensity values for the separate pixels in a group can be combined to produce a single value (referred to herein as a “collective intensity value”). The collective intensity value is sometimes also referred to as the “defect signal intensity (DSI) value”. The collective intensity value can combine and/or be based on the individual pixel intensity values for the different pixels in the group in any suitable manner. For instance, the collective intensity value can correspond to one or more the sum of the individual pixel intensity values, the product of the individual pixel intensity values, the average of the individual pixel intensity values, and/or other factors. In some example, the collective intensity value is what is compared to the first and second thresholds to determine whether the group of pixels corresponds to a detected defect (e.g., the collective intensity value satisfies the first threshold), a potential defect (e.g., the collective intensity value satisfies the second threshold but not the first threshold), or does not correspond to a defect (e.g., the collective intensity value does not satisfy either of the first threshold or the second threshold).

In some examples, where the collective intensity value satisfies the second threshold but not the first threshold, the additional information relied on to elevate the resulting potential defect to a detected defect is based on a subsequent analysis of pixel intensity value(s) for one or more individual subsets of the pixels in the group of pixels. For instance, a relatively large defect may result in a relatively high intensity value for the corresponding individual pixel(s) in a group. As a result, the collective intensity value will likely satisfy the first threshold such that the defect can immediately be identified as a detected defect. However, a smaller defect may reflect only a relatively small amount of light that is directly centered on a single pixel in the associated group of pixels used for the initial analysis with the other pixels in the group capturing little to no light. As a result, while the pixel intensity value for the single pixel associated with the defect may be relatively high, when combined with the relatively low pixel intensity values of the other pixels in the group, the resulting collective intensity value may not be sufficient to satisfy the first threshold. However, in some examples, the high intensity value of the single pixel may be sufficient to produce a collective intensity value sufficient to satisfy the second threshold. In the latter circumstance, the group of pixels may be designated as corresponding to a potential defect.

Based on the designation of a potential defect, the group of pixels may be divided into multiple subsets of pixels, some or all of which may then be analyzed in isolation against a third threshold. In some examples, the third threshold corresponds to the first threshold multiplied by some fractional multiplier (e.g., a multiplier less than 1 (e.g., 0.2, 0.25, 0.3, 0.4, 0.5, etc.)). Thus, in some examples, the third threshold is less than the first threshold. In some examples, how much less the third threshold is than the second threshold depends on how many pixels are included in the isolated subsets of pixels relative to the number of pixels included in the entire group. In some examples, an isolated subset of the group of pixels includes more than one pixel but less than all pixels in the group. In other examples, an isolated subset of the group of pixels includes only a single pixel.

In some examples, if an intensity value based on the pixel intensity data for the pixels in any one of the isolated subsets satisfies (e.g., is equal to and/or exceeds) the third threshold, the entire group of pixels is designated as corresponding to a detected defect. Additionally or alternatively, in some examples, the particular isolated subset of pixels that satisfied the third threshold are identified and designated as corresponding to a detected defect. For purposes of distinction from the collective intensity value (based on the pixel intensity data for all pixels in the group of pixels), the intensity value for an isolated subset of the pixels in the group is referred to herein as “an isolated intensity value”. In some examples, the isolated intensity value is calculated in the same way as the collective intensity value (except for the number of pixels included in the analysis). In other examples, the isolated intensity value is calculated in a different manner from the collective intensity value (e.g., one is based on a sum of individual pixel intensity values and the other is based on an average of the individual pixel intensity values). In the above scenario where only a single pixel contains a relatively high intensity value due to the small size of a defect, the subset of pixels corresponding to the single pixel result in an isolated intensity value sufficient to satisfy the third threshold. Accordingly, in some such examples, the initial designation of the group of pixels as corresponding to a potential defect (based on the collective intensity value satisfying the second threshold) is elevated to a detected defect.

The above process of analyzing pixel data at two levels of granularity can distinguish the scenario of a small defect captured by a single pixel (discussed above) and a scenario in which all pixels in an entire group have relatively high pixel intensity values due to surface roughness of the photomask rather than due to an actual defect. That is, the collective intensity values for such a group of pixels may not be sufficient to satisfy the first threshold but may be at least sufficient to satisfy the second threshold. However, the individual pixel intensity values (or some other isolated subset of the pixels) may not be sufficient to satisfy the third threshold. Accordingly, by comparing these individual pixel intensity values (e.g., isolated intensity values) to the third threshold, the group of pixels associated with a roughened surface (rather than an actual defect) will be precluded from being designated as a detected defect.

It is possible to simply perform the finer granularity analysis for all pixels in a captured image. However, the above examples disclosed herein achieve a similar (e.g., the same) result in a more computationally efficient manner by limiting the fine granularity analysis to groups of pixels that cannot be determined as either corresponding to a detected defect (by satisfying the first threshold) or not corresponding to any defect (by not satisfying either the first or second thresholds).

In some examples, potential defects are elevated to detected defects based on the fine granularity analysis (e.g., based on isolated intensity values) without regard to and/or analysis of a comparison of the rough coordinates of potential defects identified using different types of inspection processes as discussed above. In some examples, potential defects are elevated to detected defects based on the comparison of the rough coordinates of potential defects identified using a first type of inspection process to one or more different types of inspection processes without regard to and/or implementation of the fine granularity analysis. In some examples, potential defects are elevated to detected defects based on either the comparison of the rough coordinates of potential defects identified using different types of inspection processes or the implementation of the fine granularity analysis. In some such examples, the comparison of the rough coordinates of potential defects identified using different types of inspection processes is performed first and the implementation of the fine granularity analysis is skipped when the comparison of the rough coordinates determines a −19-potential defect is to be elevated to a detected defect. In other examples, the fine granularity analysis is performed first, and the comparison of the rough coordinates is skipped when the fine granularity analysis determines a potential defect is to be elevated to a detected defect. In some examples, both the fine granularity analysis and the comparison of the rough coordinates are performed regardless of the outcome of the other.

FIG. 2 illustrates an example support substrate inspection system 200 that may be implemented to detect defects in the support substrate 116 of a photomask blank (e.g., the photomask blank 500 of FIG. 5 that may be subsequently processed into a final photomask such as the photomask 102 of FIG. 1). As shown in the illustrated example, the support substrate inspection system 200 includes an optical light source 202 that shines optical light 204 onto the support substrate 116. In this example, the light 204 incident on the support substrate 116 reflects off the support substrate (as reflected light 206) towards an image sensor 208. The image sensor 208 captures an image of the support substrate 116 as illuminated by the light 204 from the optical light source 202. In some examples, as shown in FIG. 2, the image sensor 208 is positioned directly in the path of the reflected light 206. An inspection process with an image sensor 208 positioned in this manner is referred to herein as “a bright field inspection”. In some examples, an image sensor 210 can be employed and positioned at a location outside of the direct path of the reflected light 206. In such examples, the image sensor 210 captures scattered light 212 emanating from the support substrate 116 as illuminated by the optical light 204 from the optical light source 202. An inspection process with the image sensor 210 positioned outside the direct path of reflected light 206 is referred to herein as “a dark field inspection”. In some examples, only one of bright field inspection or dark field inspection is implemented. That is, in some examples, either the first image sensor 208 or the second image sensor 210 are omitted. In some examples, both bright field inspection and dark field inspection are implemented. In some such examples, the same image sensor is used for both inspection processes (e.g., by moving the image sensor in/out of the direct path of the light).

In the illustrated example of FIG. 2, the image sensor(s) 208, 210 provide image data (e.g., one or more captured images) to example photomask inspection circuitry 214 to analyze the image data to identify defects (including potential defects and detected defects) in the support substrate 116. In some examples, the photomask inspection circuitry 214 may also determine the location of the identified defects. More particularly, in some examples, the photomask inspection circuitry 214 determines rough coordinates for identified defects (including both potential defects and detected defects) and further determines precise coordinates for ones of the defects designated as detected defects. In some examples, the photomask inspection circuitry 214 determines the precise coordinates based on a precise scan and/or image focused on the areas of the support substrate 116 defined by the rough coordinates for the detected defects. In some examples, the photomask inspection circuitry 214 determines the rough coordinates for identified defects based on the particular pixels (or groups of pixels) in the image data that captured the light (e.g., the reflected light 206 and/or the scattered light 212) associated with the defects.

Determination of the rough coordinates for a particular defect using the pixel information of a captured image depends on the spatial relationship of the image sensor(s) 208, 210 and the support substrate 116. If the image sensor(s) 208, 210 are fixed relative to the substrate 116, the spatial relationship can be relatively easily defined based on an initial calibration of the image sensor(s) 208, 210. However, in some examples, the image sensor(s) 208, 210 may capture less than all of the support substrate 116 in a single image. In such examples, to cover the entire support substrate 116, the image sensor(s) 208, 210 may capture different images of different portions of the support substrate 116. The different images may be captured by moving the image sensor(s) 208, 210 relative to the support substrate 116 and/or by moving the support substrate 116 relative to the image sensor(s) 208, 210. In some examples, position control circuitry 216 controls such movement. In such examples, the position control circuitry 216 provides position data (defining the position of the image sensor(s) 208, 210, the position of the support substrate 116, and/or the relative position of the image sensor(s) 208, 210 and the support substrate 116) to the photomask inspection circuitry 214 to use in combination with the image data provided by the image sensor(s) 208, 210. The image data and the position data are collectively referred to herein as inspection data. In some examples, where the image sensors are fixed relative to the support substrate 116, the inspection data may omit the position data.

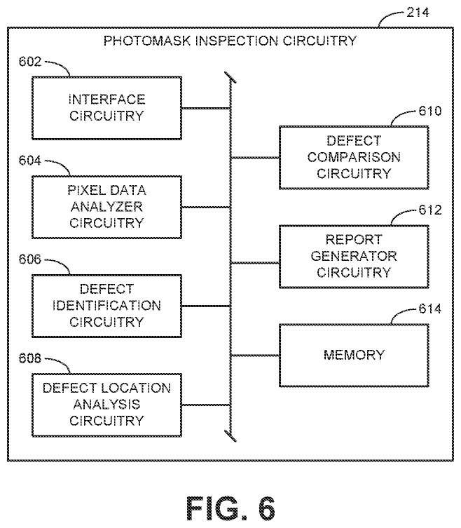

In the illustrated example of FIG. 2, the position control circuitry 216 is distinct and separate from the photomask inspection circuitry 214. However, in some examples, the photomask inspection circuitry 214 includes, implements, and/or directs the operation of the position control circuitry 216. That is, in some examples, the photomask inspection circuitry 214 controls relative movement (if any) between the image sensor(s) 208, 210 and the support substrate 115. Further, in some example, the photomask inspection circuitry 214 may be in communication with and/or direct operations of the image sensor(s) 208, 210 and/or the optical light source 202. In other examples, the image sensor(s) 208, 210 and/or the optical light source 202 are controlled and/or operated by separate circuitry not shown in FIG. 2, and the photomask inspection circuitry 214 merely receives and processes data (e.g., inspection data) received from the image sensor(s) 208, 210, and the position control circuitry 216. Further detail regarding the implementation of the photomask inspection circuitry 214 is provided below in connection with FIG. 6.

FIG. 3 illustrates an example optical multilayer inspection system 300 that may be implemented to detect defects in the multilayer 114 of a photomask blank (e.g., the photomask blank 500 of FIG. 5 that may be subsequently processed into a final photomask such as the photomask 102 of FIG. 1). The optical multilayer inspection system 300 is implemented at a later stage than the support substrate inspection system 200 after the multilayer 114 has been added onto the support substrate 116 but before the absorber 112 has been added. In this example, the multilayer 114 includes and/or is covered by a capping layer 302. In some examples, the capping layer 302 includes at least one of carbon, boron, or ruthenium, and/or any other suitable material. In some examples, the capping layer 302 is omitted or at least deposited after the optical multilayer inspection process.

In the illustrated example of FIG. 3, the optical multilayer inspection system 300 includes the same components used in the example support substrate inspection system 200 of FIG. 2. That is, in this example, the optical multilayer inspection system 300 uses the same optical light source 202 as in FIG. 2 to produce optical light 204 that shines on and/or illuminates the surface of the multilayer 114 (e.g., the capping layer 302) in a similar manner as described above in connection with FIG. 2. Further, in this example, the optical multilayer inspection system 300 uses the same image sensor(s) 208, 210 as in FIG. 2 to capture the reflected light 206 and/or the scattered light 212 as described above in connection with FIG. 2. Further, in this example, the optical multilayer inspection system 300 uses the same position control circuitry 216 as in FIG. 2 to control movement of the image sensor(s) 208, 210 and/or the multilayer 114 (and the underlying support substrate 116) as described above in connection with FIG. 2. Finally, in this example, the optical multilayer inspection system 300 uses the same photomask inspection circuitry 214 as in FIG. 2 to identify defects and determine their locations as described above in connection with FIG. 2 and detailed further below. In short, the description of each of the components described above in connection with FIG. 2 applies equally (as suitably adapted) to the corresponding components shown in FIG. 3. Thus, the primary difference between FIGS. 2 and 3 is the part of the photomask being inspected. In FIG. 2, the support substrate is being inspected for defects, while in FIG. 3, the multilayer 114 is being inspected.

While FIG. 3 is shown and described above as being substantially the same as FIG. 2, in some examples, one or more of the components shown in FIG. 3 may be different from the corresponding components shown in FIG. 2. For instance, in some examples, an optical light source different from the optical light source 202 of FIG. 2 may be used in the optical multilayer inspection system 300 of FIG. 3. Further, image sensor(s) different from the image sensors 208, 210 of FIG. 2 may be used in the optical multilayer inspection system 300 of FIG. 3. Further, position control circuitry different from the position control circuitry 216 of FIG. 2 may be used in the optical multilayer inspection system 300 of FIG. 3.

FIG. 4 illustrates an example actinic multilayer inspection system 400 that may be implemented to detect defects in the multilayer 114 of a photomask blank (e.g., the photomask blank 500 of FIG. 5 that may be subsequently processed into a final photomask such as the photomask 102 of FIG. 1). In some examples, the actinic multilayer inspection system 400 is implemented at the same stage of manufacturing of the photomask blank 500 as when the optical multilayer inspection system 300 of FIG. 3 is implemented. That is, in some examples, there is no structural change in the photomask blank 500 between the actinic and optical multilayer inspection processes. Accordingly, in some example, the actinic multilayer inspection process is implemented before the optical multilayer inspection process. In other examples, the optical multilayer inspection process is implemented before the actinic multilayer inspection process. In some examples, both optical inspection and actinic inspection are performed on the multilayer 114 because actinic inspection is typically more sensitive to multilayer phase defects, while the optical inspection is typically more sensitive to amplitude defects.

The example actinic multilayer inspection system 400 includes a similar arrangement of components as the arrangement of components shown in the example support substrate inspection system 200 of FIG. 2 and the example optical multilayer inspection system 300 of FIG. 3. However, whereas the systems 200, 300 of FIGS. 2 and 3 are based on optical light (e.g. visible light), the actinic multilayer inspection system 400 of FIG. 4 is based on extreme ultraviolet light. Thus, in this example, the actinic multilayer inspection system 400 uses an EUV light source 402 to produce EUV light 404 that shines on the multilayer 114. Unlike optical light 204 (used in FIG. 3) that is either reflected or absorbed by the outer surface of the multilayer 114 (e.g., the capping layer 302), at least some portion of the EUV light 404 (used in FIG. 4) is able to penetrate into the multilayer 114. Thus, in the illustrated example of FIG. 4, the EUV light 404 is not only reflected (as reflected EUV light 406) and scattered (as scattered EUV light 408) at the outer surface of the multilayer 114 (e.g., at the capping layer 302), but the EUV light may also be scattered and reflected at different ones of the layers or films within the multilayer 114.

As shown in the illustrated example, the actinic multilayer inspection system 400 includes an EUV image sensor 410 to capture an image of the reflected EUV light 406. In some examples, as shown in FIG. 4, the EUV image sensor 410 is positioned directly in the path of the reflected EUV light 406 to implement bright field inspection. Additionally or alternatively, in some examples, an EUV image sensor 412 can be employed and positioned at a location outside of the direct path of the reflected EUV light 406, but in a location to capture the scattered EUV light 408 to implement dark field inspection. In some examples, only one of bright field inspection or dark field inspection are implemented. That is, in some examples, either the first EUV image sensor 410 or the second EUV image sensor 412 are omitted. In some examples, both bright field inspection and dark field inspection are implemented. In some such examples, the same EUV image sensor is used for both inspection processes. In some examples, the EUV image sensors 410, 412 operate substantially the same as the image sensors 208, 210 discussed above in connection with FIGS. 2 and 3 except that the EUV image sensors 410, 412 of FIG. 4 capture EUV light whereas the image sensors 208, 210 of FIGS. 2 and 3 capture optical light. In some examples, the same image sensor(s) can be used in FIGS. 2-4 so long as the image sensor(s) are capable of capturing both optical light and EUV light.

In the illustrated example of FIG. 4, the actinic multilayer inspection system 400 includes a position control circuitry 414 that is substantially the same or identical to the position control circuitry 216 shown in FIGS. 2 and/or 3. In some examples, the position control circuitry 414 of FIG. 4 corresponds to the position control circuitry 216 of FIGS. 2 and/or 3. Thus, the description of the position control circuitry 216 provided above in connection with FIGS. 2 and 3 applies equally (as suitably adapted) to the position control circuitry 414 of FIG. 4.

In the example of FIG. 4, the actinic multilayer inspection system 400 uses the same photomask inspection circuitry 214 as in FIGS. 2 and 3 to identify defects and determine their locations as described above and detailed further below. That is, the description of the photomask inspection circuitry 214 described above in connection with FIGS. 2 and 3 applies equally (as suitably adapted) to the photomask inspection circuitry 214 shown in FIG. 4.

FIG. 5 illustrates a completed photomask blank 500 fabricated following implementation of the inspection systems 200, 300, 400 of FIGS. 2-4. As shown in FIG. 5, the photomask blank 500 includes the absorber 112 as a nonpatterned, continuous layer of material (e.g., chromium) on the multilayer 114. In some examples, the absorber 112 on the photomask blank 500 can be subsequently patterned to include openings (e.g., the openings 120 of FIG. 1) to define a final photomask (e.g., the photomask 102 of FIG. 1) to be used for lithography. As discussed above, in some examples, the pattern of openings is positioned on the absorber 112 so that the openings are spaced apart from defects in the multilayer. Accordingly, in some examples, the positioning of the pattern of openings is determined based on the precise coordinates for the defects determined by the photomask inspection circuitry 214 as discussed above and detailed further below. In some examples, the entity that produces and inspects the photomask blank 500 (e.g., the entity that implements the photomask circuitry 214) is not the same entity that patterns the blank 500 into a final photomask 102 and uses the final photomask 102 for lithography-based fabrication processes. Accordingly, in some examples, the photomask inspection circuitry 214 generates a report, a defect map, and/or other data structure that defines the precise locations of all detected defects that can be provided with the photomask blank 500.

As shown in FIG. 5, the photomask blank includes the multilayer 114, which is typically only included in mask blanks intended for EUV lithography (as discussed above in connection with FIG. 1). However, the different types of defect inspection processes discussed above in connection with FIGS. 2-4 and detailed further below can be suitably adapted to other types of photomasks used for other types of lithography processes (e.g., using light at wavelengths other than EUV light).

FIG. 6 is a block diagram of an example implementation of the photomask inspection circuitry 214 of FIGS. 2-4 to do identify defects (and determine their precise coordinates) in a photomask blank (e.g., the mask blank 500). The photomask inspection circuitry 214 of FIGS. 2-4 may be instantiated (e.g., creating an instance of, bring into being for any length of time, materialize, implement, etc.) by programmable circuitry such as a Central Processor Unit (CPU) executing first instructions. Additionally or alternatively, the photomask inspection circuitry 214 of FIGS. 2-4 may be instantiated (e.g., creating an instance of, bring into being for any length of time, materialize, implement, etc.) by (i) an Application Specific Integrated Circuit (ASIC) and/or (ii) a Field Programmable Gate Array (FPGA) structured and/or configured in response to execution of second instructions to perform operations corresponding to the first instructions. It should be understood that some or all of the circuitry of FIG. 6 may, thus, be instantiated at the same or different times. Some or all of the circuitry of FIG. 6 may be instantiated, for example, in one or more threads executing concurrently on hardware and/or in series on hardware. Moreover, in some examples, some or all of the circuitry of FIG. 6 may be implemented by microprocessor circuitry executing instructions and/or FPGA circuitry performing operations to implement one or more virtual machines and/or containers.

As shown in FIG. 6, the example photomask inspection circuitry 214 includes example interface circuitry 602, example pixel data analyzer circuitry 604, example defect identification circuitry 606, example defect location analysis circuitry 608, example defect comparison circuitry 610, example report generator circuitry 612, and example memory 614.

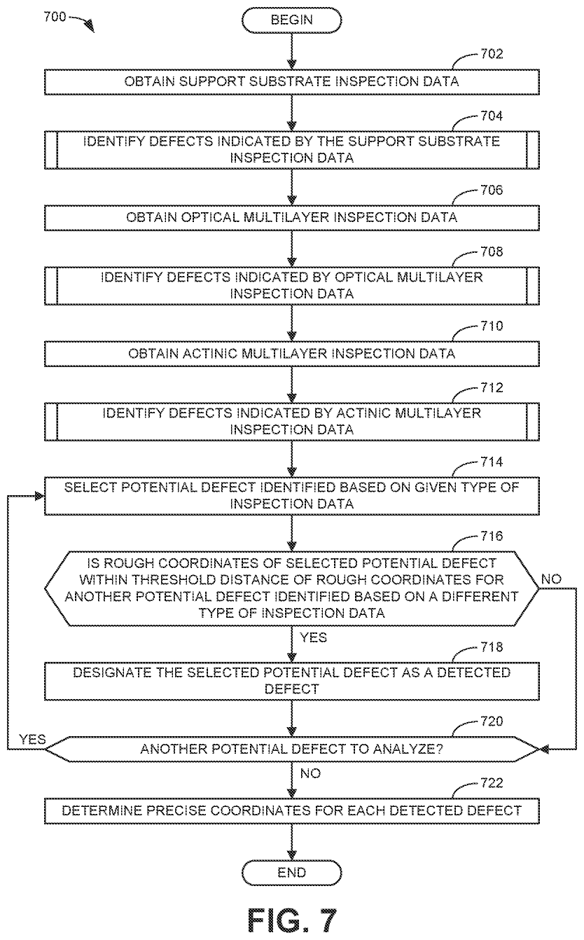

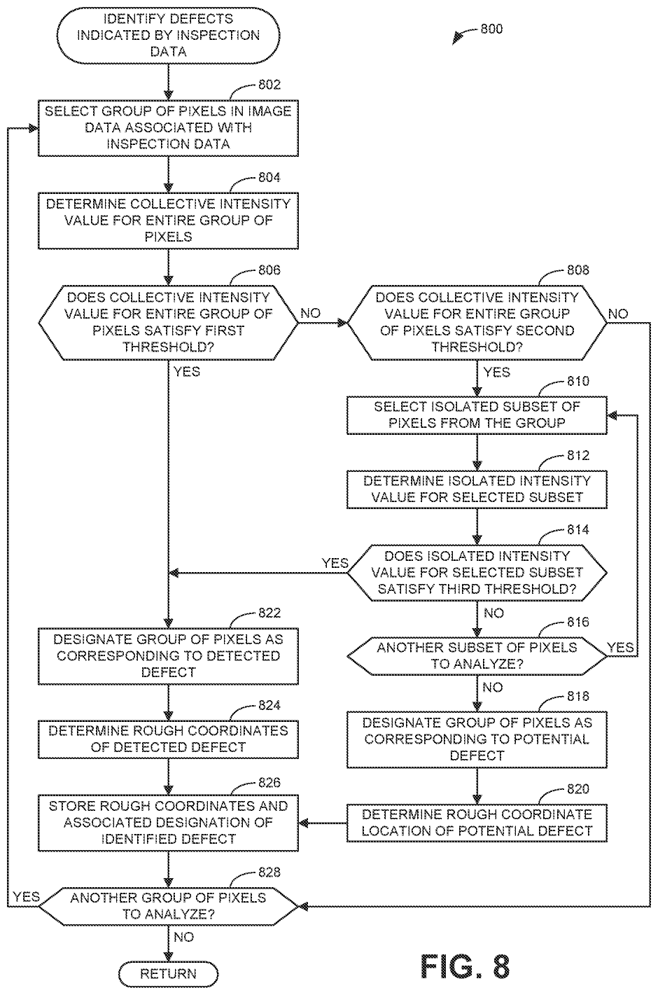

The example photomask inspection circuitry 214 is provided with the example interface circuitry 602 to enable communications with other components in any one of the example support substrate inspection system 200 of FIG. 2, the example optical multilayer inspection system 300 of FIG. 3, and/or the example actinic multilayer inspection system 400 of FIG. 4. That is, in some examples, the interface circuitry 602 receives inspection data (e.g., image data and/or position data) from the image sensor(s) 208, 210, 410, 412 and/or the position control circuitry 216, 414. In some examples, the interface circuitry 602 enables the photomask inspection circuitry 214 to control and/or otherwise direct operations of (e.g., send control signals) to the image sensor(s) 208, 210, 410, 412 and/or the position control circuitry 216, 414. Further, in some examples, the interface circuitry 602 enables the photomask inspection circuitry 214 to control and/or otherwise direct operations of (e.g., send control signals) to the optical light source 202 and/or the EUV light source 402. Additionally or alternatively, in some examples, the interface circuitry 602 enables the photomask inspection circuitry 214 to communicate with a human machine interface by outputting data (e.g., to a display screen) or receiving user inputs (e.g., via a mouse, a keyboard, a touchpad, a touchscreen, etc.). In some examples, the interface circuitry 602 is instantiated by programmable circuitry executing interface instructions and/or configured to perform operations such as those represented by the flowchart(s) of FIGS. 7 and 8.

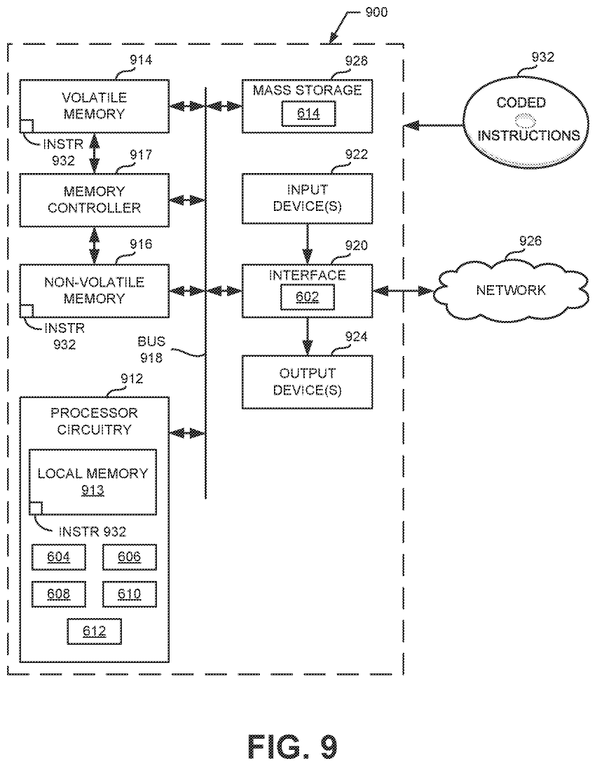

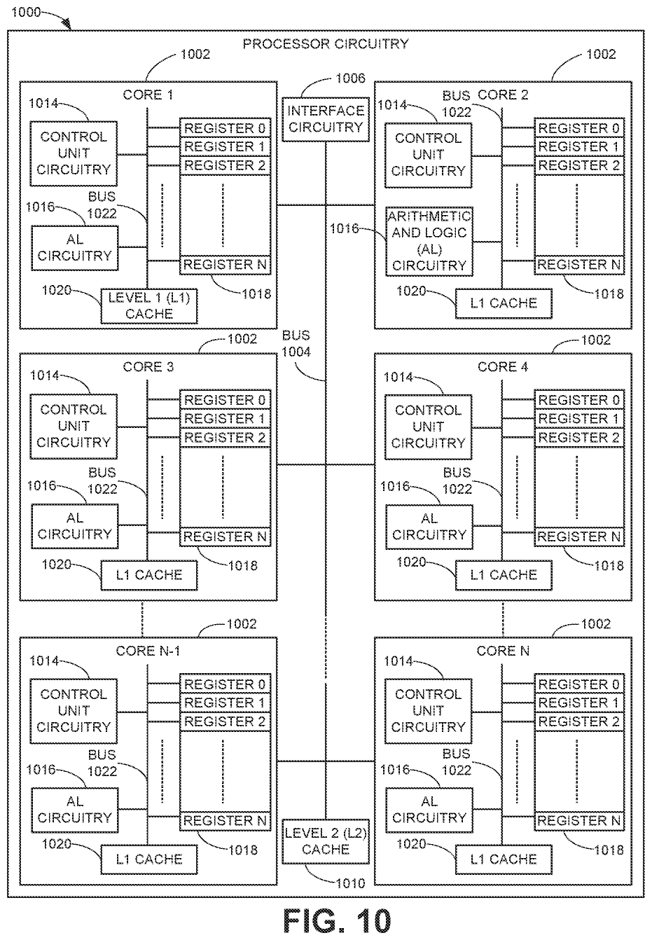

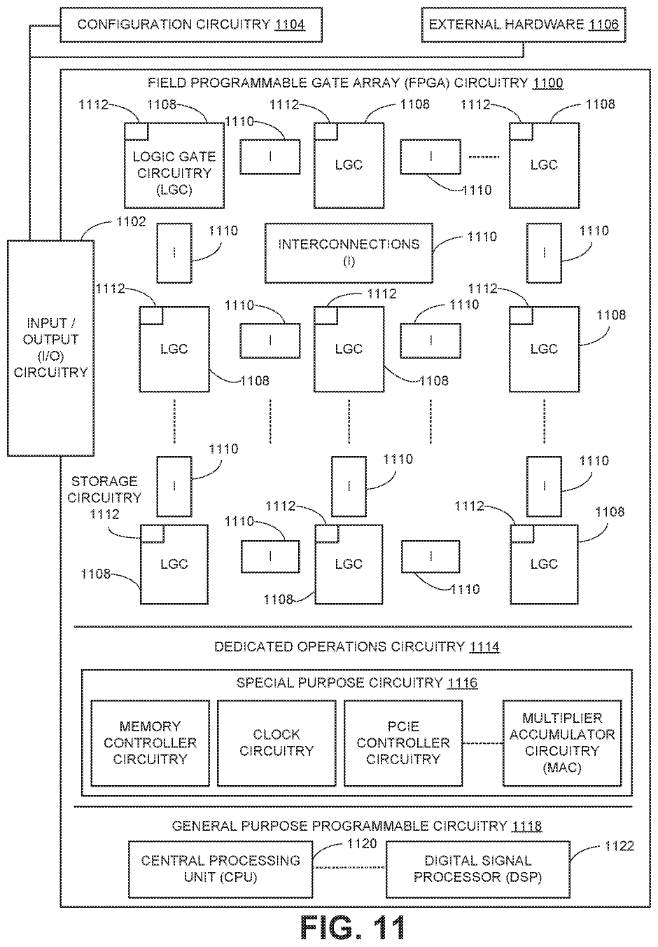

In some examples, the photomask inspection circuitry 214 includes means for communicating. For example, the means for communicating may be implemented by interface circuitry 602. In some examples, the interface circuitry 602 may be instantiated by programmable circuitry such as the example programmable circuitry 912 of FIG. 9. For instance, the interface circuitry 602 may be instantiated by the example microprocessor 1000 of FIG. 10 executing machine executable instructions such as those implemented by at least blocks 702, 706, 710 of FIG. 7. In some examples, the interface circuitry 602 may be instantiated by hardware logic circuitry, which may be implemented by an ASIC, XPU, or the FPGA circuitry 1100 of FIG. 11 configured and/or structured to perform operations corresponding to the machine readable instructions. Additionally or alternatively, the interface circuitry 602 may be instantiated by any other combination of hardware, software, and/or firmware. For example, the interface circuitry 602 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

The example photomask inspection circuitry 214 is provided with the example pixel data analyzer circuitry 604 to analyze pixel data, such as pixel intensity values, in images captures by the image sensors 208, 210, 410, 412. In some examples, the pixel data analyzer circuitry 604 determines clusters or groups of pixels to be analyzed together and determines a collective intensity value for the group of clusters. As discussed above, the collective intensity value is based on the pixel intensity values of the individual pixels in the group. Further, in some examples, the pixel data analyzer circuitry 604 divides groups of pixels into isolated subsets of pixels and determines isolated intensity values for corresponding ones of the subsets. In some examples, the pixel data analyzer circuitry 604 is instantiated by programmable circuitry executing pixel data analyzer instructions and/or configured to perform operations such as those represented by the flowchart(s) of FIGS. 7 and 8.

In some examples, the photomask inspection circuitry 214 includes means for analyzing pixels corresponding to means for grouping pixels, means for diving groups of pixels into subsets of pixels, and/or means for determining intensity values. For example, the means for analyzing may be implemented by pixel data analyzer circuitry 604. In some examples, the pixel data analyzer circuitry 604 may be instantiated by programmable circuitry such as the example programmable circuitry 912 of FIG. 9. For instance, the pixel data analyzer circuitry 604 may be instantiated by the example microprocessor 1000 of FIG. 10 executing machine executable instructions such as those implemented by at least blocks 704, 708, 712 of FIG. 7 and blocks 802, 804, 816, 828 of FIG. 8. In some examples, the pixel data analyzer circuitry 604 may be instantiated by hardware logic circuitry, which may be implemented by an ASIC, XPU, or the FPGA circuitry 1100 of FIG. 11 configured and/or structured to perform operations corresponding to the machine readable instructions. Additionally or alternatively, the pixel data analyzer circuitry 604 may be instantiated by any other combination of hardware, software, and/or firmware. For example, the pixel data analyzer circuitry 604 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

The example photomask inspection circuitry 214 is provided with the example defect identification circuitry 606 to identify defects including both potential defects and detected defects. In some examples, the defect identification circuitry 606 identifies defects by comparing the collective intensity values (determined by the pixel data analyzer circuitry 604) to various threshold. For instance, if the collective intensity value for a given group of pixels satisfies a first threshold, the example defect identification circuitry 606 designates the group of pixels as corresponding to a detected defect. If the collective intensity value for a given group of pixels does satisfy the first threshold, but satisfies a second threshold, the example defect identification circuitry 606 designates the group of pixels as corresponding to a potential defect. Further, in some such examples, the defect identification circuitry 606 may elevate the potential defect to a detected defect if the isolated intensity value for a particular subset of the pixels in the group of pixels satisfies a third threshold. In some examples, the defect identification circuitry 606 stores data indicative of identified defects in the example memory 614. That is, in some examples, the defect identification circuitry 606 associates the designation of the defect as either a potential defect or a detected defect with the associated group of pixels in a data structure in the memory 614. In some examples, the defect identification circuitry 606 is instantiated by programmable circuitry executing defect identification instructions and/or configured to perform operations such as those represented by the flowchart(s) of FIGS. 7 and 8.

In some examples, the photomask inspection circuitry 214 includes means for identifying defect corresponding to means for comparing intensity values to thresholds. For example, the means for identifying may be implemented by defect identification circuitry 606. In some examples, the defect identification circuitry 606 may be instantiated by programmable circuitry such as the example programmable circuitry 912 of FIG. 9. For instance, the defect identification circuitry 606 may be instantiated by the example microprocessor 1000 of FIG. 10 executing machine executable instructions such as those implemented by at least blocks 704, 708, 712 of FIG. 7 and blocks 806, 808, 814, 818, 822 of FIG. 8. In some examples, the defect identification circuitry 606 may be instantiated by hardware logic circuitry, which may be implemented by an ASIC, XPU, or the FPGA circuitry 1100 of FIG. 11 configured and/or structured to perform operations corresponding to the machine readable instructions. Additionally or alternatively, the defect identification circuitry 606 may be instantiated by any other combination of hardware, software, and/or firmware. For example, the defect identification circuitry 606 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

The example photomask inspection circuitry 214 is provided with the example defect location analysis circuitry 608 to determine the locations of the defects identified by the defect identification circuitry 606. More particularly, in some examples, the defect location analysis circuitry 608 determines rough coordinates for a given defect (whether a potential defect or a detected defect) based on the location of the group of pixels associated with the defect within the image data obtained from the image sensors 208, 210, 410, 412 via the interface circuitry 602. As discussed above, the rough coordinates define an approximate (e.g., relatively imprecise) location for the defect on the photomask blank 500, which is determined based on the positional relationship between the image sensors 208, 210, 410, 412 and the photomask blank 500. In some examples, if the image sensors 208, 210, 410, 412 move relative to the photomask blank 500, the defect location analysis circuitry 608 obtains their positional relationship from the position control circuitry 414. In some examples, if the image sensors 208, 210, 410, 412 are fixed relative to the photomask blank 500, their positional relationship can be determined once (e.g., during a calibration process) and then stored in the example memory 614. In such examples, the defect location analysis circuitry 608 can retrieve the positional relationship from the memory 614. In some examples, the defect location analysis circuitry 608 provides the rough coordinates determined for a given defect to the memory 614 for storage. That is, the rough coordinates are −36-leva-36-ateed in the data structure containing each group of pixels designated as corresponding to either a potential defect or a detected defect.

In some examples, in addition to determining rough coordinates for identified defects, the defect location analysis circuitry 608 also determines precise coordinates for detected pixels. As discussed above, determining precise coordinates for pixels involves additional time consuming imaging processes that include scanning the areas of the photomask blank 500 associated with the rough coordinates using magnifying optics. In some examples, the defect location analysis circuitry 608 is instantiated by programmable circuitry executing defect location analysis instructions and/or configured to perform operations such as those represented by the flowchart(s) of FIGS. 7 and 8.

In some examples, the photomask inspection circuitry 214 includes means for determining a location of a defect. For example, the means for determining may be implemented by defect location analysis circuitry 608. In some examples, the defect location analysis circuitry 608 may be instantiated by programmable circuitry such as the example programmable circuitry 912 of FIG. 9. For instance, the defect location analysis circuitry 608 may be instantiated by the example microprocessor 1000 of FIG. 10 executing machine executable instructions such as those implemented by at least blocks 704, 708, 712, 722 of FIG. 7 and blocks 820, 824 of FIG. 8. In some examples, the defect location analysis circuitry 608 may be instantiated by hardware logic circuitry, which may be implemented by an ASIC, XPU, or the FPGA circuitry 1100 of FIG. 11 configured and/or structured to perform operations corresponding to the machine readable instructions. Additionally or alternatively, the defect location analysis circuitry 608 may be instantiated by any other combination of hardware, software, and/or firmware. For example, the defect location analysis circuitry 608 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

The example photomask inspection circuitry 214 is provided with the example defect comparison circuitry 610 to compare data associated with the defects identified by the defect identification circuitry 606. More particularly, the example defect comparison circuitry 610 compares the rough coordinates (determined by the defect location analysis circuitry 608) of potential defects identified based on inspection data from different types of inspection processes. As discussed above, the different types of inspection processes can include the support substrate inspection process (discussed in connection with FIG. 2), the optical multilayer inspection process (discussed in connection with FIG. 3), and the actinic multilayer inspection process (discussed in connection with FIG. 4). In some examples, the defect comparison circuitry 610 compares the rough coordinates to determine a distance between them and then compares that distance to a threshold distance. If the distance between the rough coordinates satisfies (e.g., is less than or equal to) the distance threshold, the defect comparison circuitry 610 designates (or redesignates) the groups of pixels associated with the potential defects as detected defects. That is, the potential defects are elevated to detected defects. In some such examples, the defect comparison circuitry 610 causes the data structure stored in the example memory 614 to be updated with the new designation. In some examples, the defect comparison circuitry 610 is instantiated by programmable circuitry executing defect comparison instructions and/or configured to perform operations such as those represented by the flowchart(s) of FIGS. 7 and 8.

In some examples, the photomask inspection circuitry 214 includes means for comparing potential defects corresponding to means for comparing a distance between defects to a threshold. For example, the means for comparing may be implemented by defect comparison circuitry 610. In some examples, the defect comparison circuitry 610 may be instantiated by programmable circuitry such as the example programmable circuitry 912 of FIG. 9. For instance, the defect comparison circuitry 610 may be instantiated by the example microprocessor 1000 of FIG. 10 executing machine executable instructions such as those implemented by at least blocks 714, 716, 718, 720 of FIG. 7. In some examples, the defect comparison circuitry 610 may be instantiated by hardware logic circuitry, which may be implemented by an ASIC, XPU, or the FPGA circuitry 1100 of FIG. 11 configured and/or structured to perform operations corresponding to the machine readable instructions. Additionally or alternatively, the defect comparison circuitry 610 may be instantiated by any other combination of hardware, software, and/or firmware. For example, the defect comparison circuitry 610 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

The example photomask inspection circuitry 214 is provided with the example report generator circuitry 612 to generate a report based on the defects identified by the defect identification circuitry 606, their locations (e.g., their coordinates) determined by the defect location analysis circuitry 608, and their classification as either potential defects or detected defects as determined by the defect identification circuitry 606 and/or the defect comparison circuitry 610. In some examples, the report generator circuitry 612 generates this report based on the data structure containing such information stored in the example memory 614. The stored data structure and/or the resulting report can be in any suitable format. In some examples, the report generated by the report generator circuitry 612 is limited to the detected defects. That is, the report excludes information associated with potential defects that were never elevated to detected defects because these potential defects are likely to be false positives. In some examples, the report identifies the precise location of the detected defects so that this information can be provided to a chip manufacturing entity along with the photomask blank 500 to enable the chip manufacturing entity to determine a suitable location for openings in a pattern to be made in the absorber 112 that avoids the detected defects. In some examples, the report generator circuitry 612 is instantiated by programmable circuitry executing report generator instructions and/or configured to perform operations such as those represented by the flowchart(s) of FIGS. 7 and 8.

In some examples, the photomask inspection circuitry 214 includes means for generating a report identifying the location of detected defects. For example, the means for generating may be implemented by report generator circuitry 612. In some examples, the report generator circuitry 612 may be instantiated by programmable circuitry such as the example programmable circuitry 912 of FIG. 9. In some examples, the report generator circuitry 612 may be instantiated by hardware logic circuitry, which may be implemented by an ASIC, XPU, or the FPGA circuitry 1100 of FIG. 11 configured and/or structured to perform operations corresponding to the machine readable instructions. Additionally or alternatively, the report generator circuitry 612 may be instantiated by any other combination of hardware, software, and/or firmware. For example, the report generator circuitry 612 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

While an example manner of implementing the photomask inspection circuitry 214 of FIG. 1 is illustrated in FIG. 6, one or more of the elements, processes, and/or devices illustrated in FIG. 6 may be combined, divided, re-arranged, omitted, eliminated, and/or implemented in any other way. Further, the example interface circuitry 602, the example pixel data analyzer circuitry 604, the example defect identification circuitry 606, the example defect location analysis circuitry 608, the example defect comparison circuitry 610, the example report generator circuitry 612, the example memory 614 and/or, more generally, the example photomask inspection circuitry 214 of FIG. 6, may be implemented by hardware alone or by hardware in combination with software and/or firmware. Thus, for example, any of the example interface circuitry 602, the example pixel data analyzer circuitry 604, the example defect identification circuitry 606, the example defect location analysis circuitry 608, the example defect comparison circuitry 610, the example report generator circuitry 612, the example memory 614, and/or, more generally, the example photomask inspection circuitry 214, could be implemented by programmable circuitry in combination with machine readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), and/or field programmable logic device(s) (FPLD(s)) such as FPGAs. Further still, the example photomask inspection circuitry 214 of FIG. 6 may include one or more elements, processes, and/or devices in addition to, or instead of, those illustrated in FIG. 6, and/or may include more than one of any or all of the illustrated elements, processes and devices.

Flowchart(s) representative of example machine readable instructions, which may be executed by programmable circuitry to implement and/or instantiate the photomask inspection circuitry 214 of FIG. 6 and/or representative of example operations which may be performed by programmable circuitry to implement and/or instantiate the photomask inspection circuitry 214 of FIG. 6, are shown in FIGS. 7 and 8. The machine readable instructions may be one or more executable programs or portion(s) of one or more executable programs for execution by programmable circuitry such as the programmable circuitry 912 shown in the example processor platform 900 discussed below in connection with FIG. 9 and/or may be one or more function(s) or portion(s) of functions to be performed by the example programmable circuitry (e.g., an FPGA) discussed below in connection with FIGS. 10 and/or 11. In some examples, the machine readable instructions cause an operation, a task, etc., to be carried out and/or performed in an automated manner in the real world. As used herein, “automated” means without human involvement.

The program may be embodied in instructions (e.g., software and/or firmware) stored on one or more non-transitory computer readable and/or machine readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer readable and/or machine readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIGS. 7 and 8, many other methods of implementing the example photomask inspection circuitry 214 may alternatively be used. For example, the order of execution of the blocks of the flowchart(s) may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)). For example, the programmable circuitry may be a CPU and/or an FPGA located in the same package (e.g., the same integrated circuit (IC) package or in two or more separate housings), one or more processors in a single machine, multiple processors distributed across multiple servers of a server rack, multiple processors distributed across one or more server racks, etc., and/or any combination(s) thereof.

The machine readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, and/or produce machine executable instructions. For example, the machine readable instructions may be fragmented and stored on one or more storage devices, disks and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of computer-executable and/or machine executable instructions that implement one or more functions and/or operations that may together form a program such as that described herein.

In another example, the machine readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable, computer readable and/or machine readable media, as used herein, may include instructions and/or program(s) regardless of the particular format or state of the machine readable instructions and/or program(s).

The machine readable instructions described herein can be represented by any past, present, or future instruction language, scripting language, programming language, etc. For example, the machine readable instructions may be represented using any of the following languages: C, C++, Java, C#, Perl, Python, JavaScript, HyperText Markup Language (HTML), Structured Query Language (SQL), Swift, etc.

As mentioned above, the example operations of FIGS. 7 and 8 may be implemented using executable instructions (e.g., computer readable and/or machine readable instructions) stored on one or more non-transitory computer readable and/or machine readable media. As used herein, the terms non-transitory computer readable medium, non-transitory computer readable storage medium, non-transitory machine readable medium, and/or non-transitory machine readable storage medium are expressly defined to include any type of computer readable storage device and/or storage disk and to exclude propagating signals and to exclude transmission media. Examples of such non-transitory computer readable medium, non-transitory computer readable storage medium, non-transitory machine readable medium, and/or non-transitory machine readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer readable storage device” and “non-transitory machine readable storage device” are defined to include any physical (mechanical, magnetic and/or electrical) hardware to retain information for a time period, but to exclude propagating signals and to exclude transmission media. Examples of non-transitory computer readable storage devices and/or non-transitory machine readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer-readable instructions, machine-readable instructions, etc.

FIG. 7 is a flowchart representative of example machine readable instructions and/or example operations 700 that may be executed, instantiated, and/or performed by programmable circuitry to identify detected defects in a photomask blank and determine the precise coordinates of such defects within the blank. The example machine-readable instructions and/or the example operations 700 of FIG. 7 begin at block 702, at which the example interface circuitry 602 obtains support substrate inspection data. In some examples, the support substrate inspection data includes image data from the image sensors 208, 210 associated with the support substrate inspection system 200 of FIG. 2. In some examples, the support substrate inspection data also includes position data defining the positional relationship between the image sensors 208, 210 and the photomask blank. In some examples, the photomask inspection circuitry 214 controls and/or directs operation of the optical light source 202, the image sensors 208, 210, and/or the position control circuitry 216 of the support substrate inspection system 200 of FIG. 2 to perform an associated support substrate inspection process to obtain the inspection data. In other examples, the inspection process of the support substrate inspection system 200 is implemented independent of the photomask inspection circuitry 214 and the results (e.g., the inspection data) are then provided to the photomask inspection circuitry 214.

At block 704, the example photomask inspection circuitry 214 (e.g., using the pixel data analyzer circuitry 604, the defect identification circuitry 606, and the defect location analysis circuitry 608) identifies defects indicated by the support substrate inspection data. Further detail regarding the implementation of block 704 is provided below in connection with FIG. 8. However, to briefly summarize, through the implementation of block 704 (as detailed in FIG. 8), intensity values associated with different groups of pixels and/or subsets of pixels in such groups are analyzed to determine whether the different groups of pixels are to be designated as associated with either a potential defect or a detected defect. Further, through the implementation of block 704 (as detailed in FIG. 8), rough coordinates for the potential defects and the detected defects are determined.

At block 706, the example interface circuitry 602 obtains optical multilayer inspection data. In some examples, the optical multilayer inspection data includes image data from the image sensors 208, 210 associated with the optical multilayer inspection system 300 of FIG. 3. In some examples, the optical multilayer inspection data also includes position data defining the positional relationship between the image sensors 208, 210 and the photomask blank. In some examples, the photomask inspection circuitry 214 controls and/or directs operation of the optical light source 202, the image sensors 208, 210, and/or the position control circuitry 216 of the optical multilayer inspection system 300 of FIG. 3 to perform an associated optical multilayer inspection process to obtain the inspection data. In other examples, the inspection process of the optical multilayer inspection system 300 is implemented independent of the photomask inspection circuitry 214 and the results (e.g., the inspection data) are then provided to the photomask inspection circuitry 214.

At block 708, the example photomask inspection circuitry 214 (e.g., using the pixel data analyzer circuitry 604, the defect identification circuitry 606, and the defect location analysis circuitry 608) identifies defects indicated by the optical multilayer inspection data. Further detail regarding the implementation of block 708 is provided below in connection with FIG. 8.

At block 710, the example interface circuitry 602 obtains actinic multilayer inspection data. In some examples, the actinic multilayer inspection data includes image data from the EUV image sensors 410, 412 associated with the actinic multilayer inspection system 400 of FIG. 4. In some examples, the actinic multilayer inspection data also includes position data defining the positional relationship between the EUV image sensors 410, 412 and the photomask blank. In some examples, the photomask inspection circuitry 214 controls and/or directs operation of the EUV light source 202, the EUV image sensors 410, 412, and/or the position control circuitry 414 of the actinic multilayer inspection system 400 of FIG. 4 to perform an associated optical multilayer inspection process to obtain the inspection data. In other examples, the inspection process of the optical multilayer inspection system 400 is implemented independent of the photomask inspection circuitry 214 and the results (e.g., the inspection data) are then provided to the photomask inspection circuitry 214.

At block 712, the example photomask inspection circuitry 214 (e.g., using the pixel data analyzer circuitry 604, the defect identification circuitry 606, and the defect location analysis circuitry 608) identifies defects indicated by the actinic multilayer inspection data. Further detail regarding the implementation of block 712 is provided below in connection with FIG. 8. Thus, the flowchart of FIG. 8 is generic to each of block 704, block 708, and block 712 with variations in the implementation between the different types of inspection data discussed below.

At block 714, the example defect comparison circuitry 610 selects a potential defect identified based on a given type of inspection data (e.g., support substrate inspection data, optical multilayer inspection data, or actinic multilayer inspection data). In this example, the potential defect can correspond to a defect identified in connection with the implementation of different ones of the blocks 704, 708, and 712.

At block 716, the example defect comparison circuitry 610 determines whether the rough coordinates of the selected potential defect is within a threshold distance of the rough coordinates for another potential defect identified based on a different type of inspection data. For instance, if the selected potential defect is identified based on actinic multilayer inspection data, the example defect comparison circuitry 610 determines (at block 716) whether there is a potential defect identified based on the support substrate inspection data or the optical multilayer inspection data at the same location (within the threshold distance). If so, control advances to block 718 where the example defect comparison circuitry 610 designated (or redesignates) the selected potential defect as a detected defect. Thereafter, control advances to block 720. Returning to block 716, if the example defect comparison circuitry 610 determines there is no other potential defect within the threshold distance of the selected defect, control advances directly to block 720. That is, the selected potential defect is not elevated to a detected defect.

At block 720, the example defect comparison circuitry 610 determines whether there is another potential defect to analyze. If so, control returns to block 714 to select another potential defect and repeat the process of blocks 714-718. In some examples, the default type of inspection data relied on to select the potential defects for the analysis of blocks 714-718 is the actinic multilayer inspection data. That is, in some examples, the process of blocks 714-718 involves comparing potential defects identified based on actinic multilayer inspection relative to potential defects identified based on support substrate inspection and/or optical multilayer inspection. However, in other examples, the potential defects identified by support substrate inspection and optical multilayer inspection may additional or alternatively be compared to each other.

In some examples, the timing of blocks 714-718 within the overall process flow can be different than what is represented in FIG. 7. Specifically, as shown in the illustrated examples, blocks 714-718 are implemented after all defects have been identified (e.g., after the completion of blocks 704, 708, and 712). However, in some examples, each time another potential defect is identified, blocks 716 and 718 may be implemented to determine whether the potential defect is to be elevated to or redesignated as a detected defect before moving on to identify additional defects. In such examples, block 714 and 720 may be omitted in FIG. 7 and incorporated into the implementation of blocks 704, 708, and 712 as detailed further below in connection with FIG. 8. In other examples, block 714-720 can be omitted altogether.

If the example defect comparison circuitry 610 determines (at block 720) that there are no additional defects to analyze, control advances to block 722. At block 722, the example defect location analysis circuitry 608 determines the precise coordinates for each detected defect. In some examples, this is accomplished through a precise scan of the area defined by the rough coordinates for each detected defect using magnifying optics. Thereafter, the example process of FIG. 7 ends.

FIG. 8 is a flowchart representative of example machine readable instructions and/or example operations 800 that may be executed, instantiated, and/or performed by programmable circuitry to implement any one of blocks 704, 708, and 712 of FIG. 7 to identify defects indicated by inspection data. As discussed above, the inspection data associated with each one of blocks 704, 706, and 712 is different. As such, the generic flowchart represented in FIG. 8 for these blocks may be suitably adapted to the different types of inspection data as discussed further below.

The example machine-readable instructions and/or the example operations 800 of FIG. 8 begin at block 802, at which the example pixel data analyzer circuitry 604 selects a group of pixels in the image data associated with the inspection data. At block 804, the example pixel data analyzer circuitry 604 determines a collective intensity value for the entire group of pixels. In some examples, the collective intensity value corresponds to the sum of the individual pixel intensity values for each pixel in the group.

At block 806, the example defect identification circuitry 606 determines whether the collective intensity value for the entire group of pixels satisfies a first threshold. In some examples, the first threshold can differ depending on the type of inspection data under analysis during the implementation of the example process of FIG. 8 (e.g., support substrate inspection data, optical multilayer inspection data, or actinic multilayer inspection data). In other examples, the same value for the first threshold may be used for more than one type of inspection data. As discussed above, in some examples, the first threshold is set so as to exclude most if not all false positive identifications of defects. That is, the first threshold is set so that, if satisfied by the collective intensity value for a group of pixels, there is a relatively high degree of confidence that the group of pixels correspond to an actual defect. Accordingly, if the answer to block 806 is YES, control advances to block 822 where the example defect identification circuitry 606 designates the group of pixels as corresponding to a detected defect. Thereafter, at block 824, the example defect location analysis circuitry 608 determines rough coordinates for the detected defect.

At block 826, the example memory stores the rough coordinates and the associated designation of the identified defect (whether a potential defect or a detected defect). At block 828, the pixel data analyzer circuitry 604 determines whether there is another group of pixels to analyze. If so, control returns to block 802 to select another group of pixels to repeat the process.

Returning to block 806, if the example defect identification circuitry 606 determines the collective intensity value for the group of pixels does not satisfy the first threshold, control advances to block 808. At block 808, the example defect identification circuitry 606 determines whether the collective intensity value for the entire group of pixels satisfies a second threshold. In some examples, the second threshold can differ depending on the type of inspection data under analysis during the implementation of the example process of FIG. 8 (e.g., support substrate inspection data, optical multilayer inspection data, or actinic multilayer inspection data). In other examples, the same value for the second threshold may be used for more than one type of inspection data. As discussed above, in some examples, the second threshold is set so as to exclude most if not all false negative identifications of defects. That is, the second threshold is set so that there is a relatively high degree of confidence that no legitimate defects are missed (e.g., few if any defects fail to be identified). As such, if the answer to block 808 is NO, there is a high degree of confidence that the group of pixels are not associated with an actual defect. Accordingly, control immediately advances to block 828 to determine whether there is another group of pixels to analyze.

Notably, setting the second threshold to exclude most if not all false negatives is likely to lead to many false positions. Accordingly, defects identified by satisfying this threshold (but not the first threshold) are designated as potential defects unless and until additional analysis provides corroborating evidence to increase the confidence that the identified defect is an actual defect instead of a false positive. In such situations, the potential defect is redesignated as −56-levated to a detected defect as detailed in the subsequent blocks in the flowchart of FIG. 8 following an answer of YES at block 808.

At block 810, the example pixel data analyzer circuitry 605 selects an isolated subset of pixels from the group of pixels being analyzed (e.g., the group of pixels selected at block 802). At block 812, the example pixel data analyzer circuitry 605 determines an isolated intensity value for the selected subset. At block 814, the defect identification circuitry 606 determines whether the isolated intensity value for the selected subset satisfies a third threshold. In some examples, the third threshold can differ depending on the type of inspection data under analysis during the implementation of the example process of FIG. 8 (e.g., support substrate inspection data, optical multilayer inspection data, or actinic multilayer inspection data). In other examples, the same value for the third threshold may be used for more than one type of inspection data. In some examples, the third threshold is set so as to exclude false negative identifications of defects that may arise from relatively high intensity values spread across all pixels in the group of pixels (e.g., due to surface roughness of the portion of the photomask being analyzed) but that are not associated with an actual defect. However, the threshold is set so that defects limited to areas smaller than all pixels in the entire group (e.g., relatively small defects) may be identified based on the smaller isolated subset of pixels used for this secondary analysis. As such, if the answer to block 814 is YES, this provides the corroborating evidence to confirm there is an actual defect at the location under analysis. Accordingly, control advances to block 822 to designate the group of pixels as corresponding to a detected defect. If, on the other hand, the example defect identification circuitry 606 determines the isolated intensity value for the selected subset of pixels does not satisfy the third threshold, control advances to block 816.

At block 816, the example pixel data analyzer circuitry 604 determines whether there is another subset of pixels to analyze. If so, control returns to block 810. Otherwise, control advances to block 818. In some examples, blocks 810-816 may be omitted for certain types of inspection data and implemented for other types of inspection data (e.g., support substrate inspection data, optical multilayer inspection data, actinic multilayer inspection data). In some examples, blocks 810-816 may be omitted from the flowchart of FIG. 8 for all types of inspection data.

At block 818, the example defect identification circuitry 606 designates the group of pixels as corresponding to a potential defect. At block 820, the example defect location analysis circuitry 608 determines rough coordinates for the potential defect. Thereafter, control advances to block 826 to store the rough coordinates and the associated designation of the identified defect before advancing to block 828. If the pixel data analyzer circuitry 604 determines (at block 828) that there are no other groups of pixels to analyze, the example process of FIG. 8 ends and returns to complete the process of FIG. 7.

As discussed above, in some examples, the functionality of blocks 714-718 of FIG. 7 can be implemented at the same time that each new defect is identified. That is, at least some of blocks 714-718 of FIG. 7 may alternatively be implemented within the process flow illustrated by the example flowchart of FIG. 8. As noted above, blocks 714-718 are specific to potential defects (as opposed to detected defects) and so would only become relevant in the flowchart of FIG. 8 following an answer of YES to block 808. Accordingly, in some examples, block 714 of FIG. 7 may be implemented between blocks 808 and 810 of FIG. 8 with an answer of YES advancing control to block 822 (providing the functionality of block 718 of FIG. 7) and an answer of NO advancing control to block 810. In other examples, block 714 of FIG. 7 may be implemented between blocks 816 and 818 of FIG. 8 with an answer of YES advancing control to block 822 (providing the functionality of block 718 of FIG. 7) and an answer of NO advancing control to block 818. In some examples, block 714 is implemented within the flowchart of FIG. 8 as outlined above for some types of inspection data and block 714 is omitted for other types of inspection data. For instance, inasmuch as block 714 depends on other types of inspection data having already been analyzed, block 714 may be omitted when the flowchart of FIG. 8 is implemented in connection with the support substrate inspection data (e.g., during the implementation of block 704) and included in the flowchart of FIG. 8 when implemented in connection with at least one of the optical multilayer inspection data (e.g., during the implementation of block 708) or the actinic optical multilayer inspection data (e.g., during the implementation of block 712).

In some examples, defects in the support substrate 116 may not affect the operation of a resulting photomask manufactured from the mask blank 500 so long as such defects do not cause defects in the multilayer 114 deposited on the support substrate 116. Accordingly, in some examples, there is no need to distinguish between potential defects and detected defects in the support substrate 116. Rather, in some examples, any defects identified in the support substrate 116 are designated as potential defects without further analysis. Accordingly, in some examples, at least for support substrate inspection data (e.g., associated with the implementation of block 704 of FIG. 7), the flowchart of FIG. 8 can be significantly simplified by comparing the collective intensity value for an entire group of pixels to a single threshold (e.g., the first threshold, the second threshold, or some other threshold) to determine whether or not the group of pixels are to be designated as associated with a potential defect. In such examples, the potential defects would only be elevated to a detected defect based on the comparison of the rough coordinates of such potential defects with the rough coordinates of other defects identified using a different type of inspection data (as discussed above in connection with block 714-720 of FIG. 7).

FIG. 9 is a block diagram of an example programmable circuitry platform 900 structured to execute and/or instantiate the example machine-readable instructions and/or the example operations of FIGS. 7 and 8 to implement the photomask inspection circuitry 214 of FIG. 6. The programmable circuitry platform 900 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a headset (e.g., an augmented reality (AR) headset, a virtual reality (VR) headset, etc.) or other wearable device, or any other type of computing and/or electronic device.

The programmable circuitry platform 900 of the illustrated example includes programmable circuitry 912. The programmable circuitry 912 of the illustrated example is hardware. For example, the programmable circuitry 912 can be implemented by one or more integrated circuits, logic circuits, FPGAs, microprocessors, CPUs, GPUs, DSPs, and/or microcontrollers from any desired family or manufacturer. The programmable circuitry 912 may be implemented by one or more semiconductor based (e.g., silicon based) devices. In this example, the programmable circuitry 912 implements the example pixel data analyzer circuitry 604, example defect identification circuitry 606, example defect location analysis circuitry 608, example defect comparison circuitry 610, example report generator circuitry 612, and example memory 614.

The programmable circuitry 912 of the illustrated example includes a local memory 913 (e.g., a cache, registers, etc.). The programmable circuitry 912 of the illustrated example is in communication with main memory 914, 916, which includes a volatile memory 914 and a non-volatile memory 916, by a bus 918. The volatile memory 914 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 916 may be implemented by flash memory and/or any other desired type of memory device. Access to the main memory 914, 916 of the illustrated example is controlled by a memory controller 917. In some examples, the memory controller 917 may be implemented by one or more integrated circuits, logic circuits, microcontrollers from any desired family or manufacturer, or any other type of circuitry to manage the flow of data going to and from the main memory 914, 916.

The programmable circuitry platform 900 of the illustrated example also includes interface circuitry 920. The interface circuitry 920 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 922 are connected to the interface circuitry 920. The input device(s) 922 permit(s) a user (e.g., a human user, a machine user, etc.) to enter data and/or commands into the programmable circuitry 912. The input device(s) 922 can be implemented by, for example, an audio sensor, a microphone, a camera (still or video), a keyboard, a button, a mouse, a touchscreen, a trackpad, a trackball, an isopoint device, and/or a voice recognition system.

One or more output devices 924 are also connected to the interface circuitry 920 of the illustrated example. The output device(s) 924 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 920 of the illustrated example, thus, typically includes a graphics driver card, a graphics driver chip, and/or graphics processor circuitry such as a GPU.

The interface circuitry 920 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 926. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 900 of the illustrated example also includes one or more mass storage discs or devices 928 to store firmware, software, and/or data. Examples of such mass storage discs or devices 928 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine readable instructions 932, which may be implemented by the machine readable instructions of FIGS. 7 and 8, may be stored in the mass storage device 928, in the volatile memory 914, in the non-volatile memory 916, and/or on at least one non-transitory computer readable storage medium such as a CD or DVD which may be removable.

FIG. 10 is a block diagram of an example implementation of the programmable circuitry 912 of FIG. 9. In this example, the programmable circuitry 912 of FIG. 9 is implemented by a microprocessor 1000. For example, the microprocessor 1000 may be a general-purpose microprocessor (e.g., general-purpose microprocessor circuitry). The microprocessor 1000 executes some or all of the machine-readable instructions of the flowcharts of FIGS. 7 and 8 to effectively instantiate the circuitry of FIG. 6 as logic circuits to perform operations corresponding to those machine readable instructions. In some such examples, the circuitry of FIG. 6 is instantiated by the hardware circuits of the microprocessor 1000 in combination with the machine-readable instructions. For example, the microprocessor 1000 may be implemented by multi-core hardware circuitry such as a CPU, a DSP, a GPU, an XPU, etc. Although it may include any number of example cores 1002 (e.g., 1 core), the microprocessor 1000 of this example is a multi-core semiconductor device including N cores. The cores 1002 of the microprocessor 1000 may operate independently or may cooperate to execute machine readable instructions. For example, machine code corresponding to a firmware program, an embedded software program, or a software program may be executed by one of the cores 1002 or may be executed by multiple ones of the cores 1002 at the same or different times. In some examples, the machine code corresponding to the firmware program, the embedded software program, or the software program is split into threads and executed in parallel by two or more of the cores 1002. The software program may correspond to a portion or all of the machine readable instructions and/or operations represented by the flowcharts of FIGS. 7 and 8.

The cores 1002 may communicate by a first example bus 1004. In some examples, the first bus 1004 may be implemented by a communication bus to effectuate communication associated with one(s) of the cores 1002. For example, the first bus 1004 may be implemented by at least one of an Inter-Integrated Circuit (I2C) bus, a Serial Peripheral Interface (SPI) bus, a PCI bus, or a PCIe bus. Additionally or alternatively, the first bus 1004 may be implemented by any other type of computing or electrical bus. The cores 1002 may obtain data, instructions, and/or signals from one or more external devices by example interface circuitry 1006. The cores 1002 may output data, instructions, and/or signals to the one or more external devices by the interface circuitry 1006. Although the cores 1002 of this example include example local memory 1020 (e.g., Level 1 (L1) cache that may be split into an L1 data cache and an L1 instruction cache), the microprocessor 1000 also includes example shared memory 1010 that may be shared by the cores (e.g., Level 2 (L2 cache)) for high-speed access to data and/or instructions. Data and/or instructions may be transferred (e.g., shared) by writing to and/or reading from the shared memory 1010. The local memory 1020 of each of the cores 1002 and the shared memory 1010 may be part of a hierarchy of storage devices including multiple levels of cache memory and the main memory (e.g., the main memory 914, 916 of FIG. 9). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 1002 may be referred to as a CPU, DSP, GPU, etc., or any other type of hardware circuitry. Each core 1002 includes control unit circuitry 1014, arithmetic and logic (AL) circuitry (sometimes referred to as an ALU) 1016, a plurality of registers 1018, the local memory 1020, and a second example bus 1022. Other structures may be present. For example, each core 1002 may include vector unit circuitry, single instruction multiple data (SIMD) unit circuitry, load/store unit (LSU) circuitry, branch/jump unit circuitry, floating-point unit (FPU) circuitry, etc. The control unit circuitry 1014 includes semiconductor-based circuits structured to control (e.g., coordinate) data movement within the corresponding core 1002. The AL circuitry 1016 includes semiconductor-based circuits structured to perform one or more mathematic and/or logic operations on the data within the corresponding core 1002. The AL circuitry 1016 of some examples performs integer based operations. In other examples, the AL circuitry 1016 also performs floating-point operations. In yet other examples, the AL circuitry 1016 may include first AL circuitry that performs integer-based operations and second AL circuitry that performs floating-point operations. In some examples, the AL circuitry 1016 may be referred to as an Arithmetic Logic Unit (ALU).

The registers 1018 are semiconductor-based structures to store data and/or instructions such as results of one or more of the operations performed by the AL circuitry 1016 of the corresponding core 1002. For example, the registers 1018 may include vector register(s), SIMD register(s), general-purpose register(s), flag register(s), segment register(s), machine-specific register(s), instruction pointer register(s), control register(s), debug register(s), memory management register(s), machine check register(s), etc. The registers 1018 may be arranged in a bank as shown in FIG. 10. Alternatively, the registers 1018 may be organized in any other arrangement, format, or structure, such as by being distributed throughout the core 1002 to shorten access time. The second bus 1022 may be implemented by at least one of an I2C bus, a SPI bus, a PCI bus, or a PCIe bus.

Each core 1002 and/or, more generally, the microprocessor 1000 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 1000 is a semiconductor device fabricated to include many transistors interconnected to implement the structures described above in one or more integrated circuits (ICs) contained in one or more packages.

The microprocessor 1000 may include and/or cooperate with one or more accelerators (e.g., acceleration circuitry, hardware accelerators, etc.). In some examples, accelerators are implemented by logic circuitry to perform certain tasks more quickly and/or efficiently than can be done by a general-purpose processor. Examples of accelerators include ASICs and FPGAs such as those discussed herein. A GPU, DSP and/or other programmable device can also be an accelerator. Accelerators may be on-board the microprocessor 1000, in the same chip package as the microprocessor 1000 and/or in one or more separate packages from the microprocessor 1000.

FIG. 11 is a block diagram of another example implementation of the programmable circuitry 912 of FIG. 9. In this example, the programmable circuitry 912 is implemented by FPGA circuitry 1100. For example, the FPGA circuitry 1100 may be implemented by an FPGA. The FPGA circuitry 1100 can be used, for example, to perform operations that could otherwise be performed by the example microprocessor 1000 of FIG. 10 executing corresponding machine readable instructions. However, once configured, the FPGA circuitry 1100 instantiates the operations and/or functions corresponding to the machine readable instructions in hardware and, thus, can often execute the operations/functions faster than they could be performed by a general-purpose microprocessor executing the corresponding software.

More specifically, in contrast to the microprocessor 1000 of FIG. 10 described above (which is a general purpose device that may be programmed to execute some or all of the machine readable instructions represented by the flowchart(s) of FIGS. 7 and 8 but whose interconnections and logic circuitry are fixed once fabricated), the FPGA circuitry 1100 of the example of FIG. 11 includes interconnections and logic circuitry that may be configured, structured, programmed, and/or interconnected in different ways after fabrication to instantiate, for example, some or all of the operations/functions corresponding to the machine readable instructions represented by the flowchart(s) of FIGS. 7 and 8. In particular, the FPGA circuitry 1100 may be thought of as an array of logic gates, interconnections, and switches. The switches can be programmed to change how the logic gates are interconnected by the interconnections, effectively forming one or more dedicated logic circuits (unless and until the FPGA circuitry 1100 is reprogrammed). The configured logic circuits enable the logic gates to cooperate in different ways to perform different operations on data received by input circuitry. Those operations may correspond to some or all of the instructions (e.g., the software and/or firmware) represented by the flowchart(s) of FIGS. 7 and 8. As such, the FPGA circuitry 1100 may be configured and/or structured to effectively instantiate some or all of the operations/functions corresponding to the machine readable instructions of the flowchart(s) of FIGS. 7 and 8 as dedicated logic circuits to perform the operations/functions corresponding to those software instructions in a dedicated manner analogous to an ASIC. Therefore, the FPGA circuitry 1100 may perform the operations/functions corresponding to the some or all of the machine readable instructions of FIGS. 7 and 8 faster than the general-purpose microprocessor can execute the same.

In the example of FIG. 11, the FPGA circuitry 1100 is configured and/or structured in response to being programmed (and/or reprogrammed one or more times) based on a binary file. In some examples, the binary file may be compiled and/or generated based on instructions in a hardware description language (HDL) such as Lucid, Very High Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 1100 of FIG. 11 may access and/or load the binary file to cause the FPGA circuitry 1100 of FIG. 11 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 1100 of FIG. 11 to cause configuration and/or structuring of the FPGA circuitry 1100 of FIG. 11, or portion(s) thereof.

In some examples, the binary file is compiled, generated, transformed, and/or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is compiled, generated, and/or otherwise output from the uniform software platform based on the second instructions. In some examples, the FPGA circuitry 1100 of FIG. 11 may access and/or load the binary file to cause the FPGA circuitry 1100 of FIG. 11 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 1100 of FIG. 11 to cause configuration and/or structuring of the FPGA circuitry 1100 of FIG. 11, or portion(s) thereof.

The FPGA circuitry 1100 of FIG. 11, includes example input/output (I/O) circuitry 1102 to obtain and/or output data to/from example configuration circuitry 1104 and/or external hardware 1106. For example, the configuration circuitry 1104 may be implemented by interface circuitry that may obtain a binary file, which may be implemented by a bit stream, data, and/or machine-readable instructions, to configure the FPGA circuitry 1100, or portion(s) thereof. In some such examples, the configuration circuitry 1104 may obtain the binary file from a user, a machine (e.g., hardware circuitry (e.g., programmable or dedicated circuitry) that may implement an Artificial Intelligence/Machine Learning (AI/ML) model to generate the binary file), etc., and/or any combination(s) thereof). In some examples, the external hardware 1106 may be implemented by external hardware circuitry. For example, the external hardware 1106 may be implemented by the microprocessor 1000 of FIG. 10.

The FPGA circuitry 1100 also includes an array of example logic gate circuitry 1108, a plurality of example configurable interconnections 1110, and example storage circuitry 1112. The logic gate circuitry 1108 and the configurable interconnections 1110 are configurable to instantiate one or more operations/functions that may correspond to at least some of the machine readable instructions of FIGS. 7 and 8 and/or other desired operations. The logic gate circuitry 1108 shown in FIG. 11 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 1108 to enable configuration of the electrical structures and/or the logic gates to form circuits to perform desired operations/functions. The logic gate circuitry 1108 may include other electrical structures such as look-up tables (LUTs), registers (e.g., flip-flops or latches), multiplexers, etc.

The configurable interconnections 1110 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 1108 to program desired logic circuits.

The storage circuitry 1112 of the illustrated example is structured to store result(s) of the one or more of the operations performed by corresponding logic gates. The storage circuitry 1112 may be implemented by registers or the like. In the illustrated example, the storage circuitry 1112 is distributed amongst the logic gate circuitry 1108 to facilitate access and increase execution speed.

The example FPGA circuitry 1100 of FIG. 11 also includes example dedicated operations circuitry 1114. In this example, the dedicated operations circuitry 1114 includes special purpose circuitry 1116 that may be invoked to implement commonly used functions to avoid the need to program those functions in the field. Examples of such special purpose circuitry 1116 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 1100 may also include example general purpose programmable circuitry 1118 such as an example CPU 1120 and/or an example DSP 1122. Other general purpose programmable circuitry 1118 may additionally or alternatively be present such as a GPU, an XPU, etc., that can be programmed to perform other operations.

Although FIGS. 10 and 11 illustrate two example implementations of the programmable circuitry 912 of FIG. 9, many other approaches are contemplated. For example, FPGA circuitry may include an on-board CPU, such as one or more of the example CPU 1120 of FIG. 10. Therefore, the programmable circuitry 912 of FIG. 9 may additionally be implemented by combining at least the example microprocessor 1000 of FIG. 10 and the example FPGA circuitry 1100 of FIG. 11. In some such hybrid examples, one or more cores 1002 of FIG. 10 may execute a first portion of the machine readable instructions represented by the flowchart(s) of FIGS. 7 and 8 to perform first operation(s)/function(s), the FPGA circuitry 1100 of FIG. 11 may be configured and/or structured to perform second operation(s)/function(s) corresponding to a second portion of the machine readable instructions represented by the flowcharts of FIGS. 7 and 8, and/or an ASIC may be configured and/or structured to perform third operation(s)/function(s) corresponding to a third portion of the machine readable instructions represented by the flowcharts of FIGS. 7 and 8.

It should be understood that some or all of the circuitry of FIG. 6 may, thus, be instantiated at the same or different times. For example, same and/or different portion(s) of the microprocessor 1000 of FIG. 10 may be programmed to execute portion(s) of machine-readable instructions at the same and/or different times. In some examples, same and/or different portion(s) of the FPGA circuitry 1100 of FIG. 11 may be configured and/or structured to perform operations/functions corresponding to portion(s) of machine-readable instructions at the same and/or different times.

In some examples, some or all of the circuitry of FIG. 6 may be instantiated, for example, in one or more threads executing concurrently and/or in series. For example, the microprocessor 1000 of FIG. 10 may execute machine readable instructions in one or more threads executing concurrently and/or in series. In some examples, the FPGA circuitry 1100 of FIG. 11 may be configured and/or structured to carry out operations/functions concurrently and/or in series. Moreover, in some examples, some or all of the circuitry of FIG. 6 may be implemented within one or more virtual machines and/or containers executing on the microprocessor 1000 of FIG. 10.

In some examples, the programmable circuitry 912 of FIG. 9 may be in one or more packages. For example, the microprocessor 1000 of FIG. 10 and/or the FPGA circuitry 1100 of FIG. 11 may be in one or more packages. In some examples, an XPU may be implemented by the programmable circuitry 912 of FIG. 9, which may be in one or more packages. For example, the XPU may include a CPU (e.g., the microprocessor 1000 of FIG. 10, the CPU 1120 of FIG. 11, etc.) in one package, a DSP (e.g., the DSP 1122 of FIG. 11) in another package, a GPU in yet another package, and an FPGA (e.g., the FPGA circuitry 1100 of FIG. 11) in still yet another package.

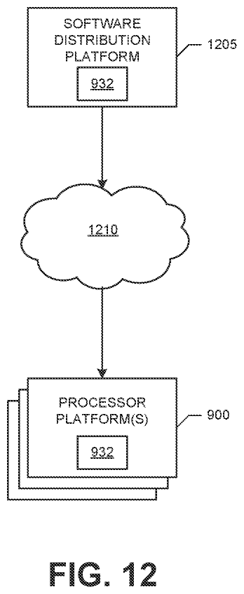

A block diagram illustrating an example software distribution platform 1205 to distribute software such as the example machine readable instructions 932 of FIG. 9 to other hardware devices (e.g., hardware devices owned and/or operated by third parties from the owner and/or operator of the software distribution platform) is illustrated in FIG. 12. The example software distribution platform 1205 may be implemented by any computer server, data facility, cloud service, etc., capable of storing and transmitting software to other computing devices. The third parties may be customers of the entity owning and/or operating the software distribution platform 1205. For example, the entity that owns and/or operates the software distribution platform 1205 may be a developer, a seller, and/or a licensor of software such as the example machine readable instructions 932 of FIG. 9. The third parties may be consumers, users, retailers, OEMs, etc., who purchase and/or license the software for use and/or re-sale and/or sub-licensing. In the illustrated example, the software distribution platform 1205 includes one or more servers and one or more storage devices. The storage devices store the machine readable instructions 932, which may correspond to the example machine readable instructions of FIGS. 7 and 8, as described above. The one or more servers of the example software distribution platform 1205 are in communication with an example network 1210, which may correspond to any one or more of the Internet and/or any of the example networks described above. In some examples, the one or more servers are responsive to requests to transmit the software to a requesting party as part of a commercial transaction. Payment for the delivery, sale, and/or license of the software may be handled by the one or more servers of the software distribution platform and/or by a third party payment entity. The servers enable purchasers and/or licensors to download the machine readable instructions 932 from the software distribution platform 1205. For example, the software, which may correspond to the example machine readable instructions of FIGS. 7 and 8, may be downloaded to the example programmable circuitry platform 900, which is to execute the machine readable instructions 932 to implement the photomask inspection circuitry 214. In some examples, one or more servers of the software distribution platform 1205 periodically offer, transmit, and/or force updates to the software (e.g., the example machine readable instructions 932 of FIG. 9) to ensure improvements, patches, updates, etc., are distributed and applied to the software at the end user devices. Although referred to as software above, the distributed “software” could alternatively be firmware.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that enable the identification of defects in photomask blanks by reducing (e.g., eliminating) both false positives and false negatives for greater accuracy than other known approaches. Furthermore, examples disclosed herein provide increased efficiencies in the defect detection process by limiting the time consuming process of determining the precise coordinates to detected defects that have been reliably confirmed to correspond to actual defects (as opposed to merely being false positive detections of defects).

Further examples and combinations thereof include the following:

Example 1 includes an apparatus comprising interface circuitry, machine readable instructions, and programmable circuitry to at least one of instantiate or execute the machine readable instructions to identify a first potential defect in a photomask blank based on an intensity value not satisfying a first threshold but satisfying a second threshold, the intensity value based on pixel data associated with a first type of inspection of the photomask blank, and designate the first potential defect as a detected defect based on first coordinates for the first potential defect being within a threshold distance of second coordinates for a second potential defect, the second potential defect identified based on a second type of inspection of the photomask blank.

Example 2 includes the apparatus of example 1, wherein the first type of inspection is an actinic multilayer inspection, and the second type of inspection is at least one of a substrate inspection or an optical multilayer inspection.

Example 3 includes the apparatus of any one of examples 1 or 2, wherein the intensity value is a first intensity value, and the detected defect is a first detected defect, the programmable circuitry to identify a second detected defect based on a second intensity value of the pixel data satisfying the first threshold.

Example 4 includes the apparatus of any one of examples 1-3, wherein the programmable circuitry is to determine second coordinates for the detected defect, the second coordinates more precise than the first coordinates.

Example 5 includes the apparatus of any one of examples 1-4, wherein the intensity value is a collective intensity value based on multiple pixel values of a group of pixels in the pixel data, the programmable circuitry to determine an isolated intensity value for an isolated subset of the group of pixels, and designate the first potential defect as a detected defect based on the isolated intensity value satisfying a third threshold.

Example 6 includes the apparatus of example 5, wherein a number of pixels in the isolated subset is one.

Example 7 includes the apparatus of any one of examples 5 or 6, wherein the third threshold is less than the first threshold.

Example 8 includes a non-transitory machine readable storage medium comprising instructions to cause programmable circuitry to at least identify a first potential defect in a photomask blank based on an intensity value not satisfying a first threshold but satisfying a second threshold, the intensity value based on pixel data associated with a first type of inspection of the photomask blank, and designate the first potential defect as a detected defect based on first coordinates for the first potential defect being within a threshold distance of second coordinates for a second potential defect, the second potential defect identified based on a second type of inspection of the photomask blank.

Example 9 includes the non-transitory machine readable storage medium of example 8, wherein the first type of inspection is an actinic multilayer inspection, and the second type of inspection is at least one of a substrate inspection or an optical multilayer inspection.

Example 10 includes the non-transitory machine readable storage medium of any one of examples 8 or 9, wherein the intensity value is a first intensity value, the detected defect is a first detected defect, and the instructions cause the programmable circuitry to identify a second detected defect based on a second intensity value of the pixel data satisfying the first threshold.

Example 11 includes the non-transitory machine readable storage medium of any one of examples 8-10, wherein the instructions cause the programmable circuitry to determine second coordinates for the detected defect, the second coordinates more precise than the first coordinates.

Example 12 includes the non-transitory machine readable storage medium of any one of examples 8-12, wherein the intensity value is a collective intensity value based on multiple pixel values of a group of pixels in the pixel data, and the instructions cause the programmable circuitry to determine an isolated intensity value for an isolated subset of the group of pixels, and designate the first potential defect as a detected defect based on the isolated intensity value satisfying a third threshold.

Example 13 includes the non-transitory machine readable storage medium of example 12, wherein a number of pixels in the isolated subset is one.

Example 14 includes the non-transitory machine readable storage medium of any one of examples 12 or 13, wherein the third threshold is less than the first threshold.

Example 15 includes a method comprising identifying a first potential defect in a photomask blank based on an intensity value not satisfying a first threshold but satisfying a second threshold, the intensity value based on pixel data associated with a first type of inspection data for the photomask blank, and designating, by executing instructions with programmable circuitry, the first potential defect as a detected defect based on first coordinates for the first potential defect being within a threshold distance of second coordinates for a second potential defect, the second potential defect identified based on a second type of inspection data for the photomask blank.

Example 16 includes the method of example 15, wherein the first type of inspection data is actinic multilayer inspection data, and the second type of inspection data is at least one of substrate inspection data or optical multilayer inspection data.

Example 17 includes the method of any one of examples 15 or 16, wherein the intensity value is a first intensity value, and the detected defect is a first detected defect, the method further including identifying a second detected defect based on a second intensity value of the pixel data satisfying the first threshold.

Example 18 includes the method of any one of examples 15-17, further including determining second coordinates for the detected defect, the second coordinates more precise than the first coordinates.

Example 19 includes the method of any one of examples 15-18, wherein the intensity value is a collective intensity value based on multiple pixel values of a group of pixels in the pixel data, the method further including determining an isolated intensity value for an isolated subset of the group of pixels, and designating the first potential defect as a detected defect based on the isolated intensity value satisfying a third threshold.

Example 20 includes the method of example 19, wherein a number of pixels in the isolated subset is one.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus comprising:
interface circuitry;
machine readable instructions; and
programmable circuitry to at least one of instantiate or execute the machine readable instructions to:
identify a first potential defect in a photomask blank based on an intensity value not satisfying a first threshold but satisfying a second threshold, the intensity value based on pixel data associated with a first type of inspection of the photomask blank; and
designate the first potential defect as a detected defect based on first coordinates for the first potential defect being within a threshold distance of second coordinates for a second potential defect, the second potential defect identified based on a second type of inspection of the photomask blank.

2. The apparatus of claim 1, wherein the first type of inspection is an actinic multilayer inspection, and the second type of inspection is at least one of a substrate inspection or an optical multilayer inspection.

3. The apparatus of claim 1, wherein the intensity value is a first intensity value, and the detected defect is a first detected defect, the programmable circuitry to identify a second detected defect based on a second intensity value of the pixel data satisfying the first threshold.

4. The apparatus of claim 1, wherein the programmable circuitry is to determine second coordinates for the detected defect, the second coordinates more precise than the first coordinates.

5. The apparatus of claim 1, wherein the intensity value is a collective intensity value based on multiple pixel values of a group of pixels in the pixel data, the programmable circuitry to:
determine an isolated intensity value for an isolated subset of the group of pixels; and
designate the first potential defect as a detected defect based on the isolated intensity value satisfying a third threshold.

6. The apparatus of claim 5, wherein a number of pixels in the isolated subset is one.

7. The apparatus of claim 5, wherein the third threshold is less than the first threshold.

8. A non-transitory machine readable storage medium comprising instructions to cause programmable circuitry to at least:
identify a first potential defect in a photomask blank based on an intensity value not satisfying a first threshold but satisfying a second threshold, the intensity value based on pixel data associated with a first type of inspection of the photomask blank; and
designate the first potential defect as a detected defect based on first coordinates for the first potential defect being within a threshold distance of second coordinates for a second potential defect, the second potential defect identified based on a second type of inspection of the photomask blank.

9. The non-transitory machine readable storage medium of claim 8, wherein the first type of inspection is an actinic multilayer inspection, and the second type of inspection is at least one of a substrate inspection or an optical multilayer inspection.

10. The non-transitory machine readable storage medium of claim 8, wherein the intensity value is a first intensity value, the detected defect is a first detected defect, and the instructions cause the programmable circuitry to identify a second detected defect based on a second intensity value of the pixel data satisfying the first threshold.

11. The non-transitory machine readable storage medium of claim 8, wherein the instructions cause the programmable circuitry to determine second coordinates for the detected defect, the second coordinates more precise than the first coordinates.

12. The non-transitory machine readable storage medium of claim 8, wherein the intensity value is a collective intensity value based on multiple pixel values of a group of pixels in the pixel data, and the instructions cause the programmable circuitry to:
determine an isolated intensity value for an isolated subset of the group of pixels; and
designate the first potential defect as a detected defect based on the isolated intensity value satisfying a third threshold.

13. The non-transitory machine readable storage medium of claim 12, wherein a number of pixels in the isolated subset is one.

14. The non-transitory machine readable storage medium of claim 12, wherein the third threshold is less than the first threshold.

15. A method comprising:
identifying a first potential defect in a photomask blank based on an intensity value not satisfying a first threshold but satisfying a second threshold, the intensity value based on pixel data associated with a first type of inspection data for the photomask blank; and
designating, by executing instructions with programmable circuitry, the first potential defect as a detected defect based on first coordinates for the first potential defect being within a threshold distance of second coordinates for a second potential defect, the second potential defect identified based on a second type of inspection data for the photomask blank.

16. The method of claim 15, wherein the first type of inspection data is actinic multilayer inspection data, and the second type of inspection data is at least one of substrate inspection data or optical multilayer inspection data.

17. The method of claim 15, wherein the intensity value is a first intensity value, and the detected defect is a first detected defect, the method further including identifying a second detected defect based on a second intensity value of the pixel data satisfying the first threshold.

18. The method of claim 15, further including determining second coordinates for the detected defect, the second coordinates more precise than the first coordinates.

19. The method of claim 15, wherein the intensity value is a collective intensity value based on multiple pixel values of a group of pixels in the pixel data, the method further including:
determining an isolated intensity value for an isolated subset of the group of pixels; and
designating the first potential defect as a detected defect based on the isolated intensity value satisfying a third threshold.

20. The method of claim 19, wherein a number of pixels in the isolated subset is one.
